(19) United States
(12) Patent Application Publication
(10) Pub. No.: US 2025/0311363 A1
(43) Pub. Date: Oct. 2, 2025

(54) BACKSIDE GATE CUT FORMATION

(71) Applicant: Intel Corporation, Santa Clara, CA (US)

(72) Inventors: Feng Zhang, Portland, OR (US); Guowei Xu, Portland, OR (US); Tao Chu, Portland, OR (US); Kan Zhang, Hillsboro, OR (US); Anand Murthy, Portland, OR (US); Chun Wing Yeung, Portland, OR (US); Minwoo Jang, Portland, OR (US); Yanbin Luo, Portland, OR (US); Paul A. Packan, Hillsboro, OR (US); Ting-Hsiang Hung, Beaverton, OR (US); Robin Chao, Portland, OR (US); Chia-Ching Lin, Portland, OR (US); Chung-Hsun Lin, Portland, OR (US); Yue Zhong, Portland, OR (US); Yang Zhang, Rio Rancho, NM (US)

(21) Appl. No.: 18/621,821

(22) Filed: Mar. 29, 2024

(51) Int. Cl. H01L 29/417; H01L 27/092; H01L 29/06; H01L 29/423; H01L 29/778

(52) U.S. Cl. CPC H10D 64/258; H10D 30/47; H10D 30/6729; H10D 30/6735; H10D 62/118; H10D 84/85

(57) ABSTRACT

Techniques are provided herein to form an integrated circuit having adjacent pairs of semiconductor devices separated by dielectric walls that are formed from the backside of the structure. Neighboring semiconductor devices each include a semiconductor region extending between a source region and a drain region, and a gate structure extending over the semiconductor regions of the neighboring semiconductor devices. A dielectric wall may be present between each pair of neighboring semiconductor devices thus interrupting the gate structure. Each of the dielectric walls may be formed, for example, from the backside of the structure as a series of parallel lines across the integrated circuit. A conductive link may extend through a given dielectric wall to electrically connect the adjacent gate electrodes together. Other conductive links may also extend through the dielectric wall in the source/drain trench to connect adjacent source or drain contacts.

### BACKGROUND

As integrated circuits continue to scale downward in size, a number of challenges arise. For instance, reducing the size of memory and logic cells is becoming increasingly more difficult. Certain aspects of lithography technology can impose physical limits on how accurately certain structures can be aligned. Due to the high complexity of integrated circuit layouts, any etch processes performed through multiple materials across a given die yield possible points of failure for the device. Accordingly, there remain a number of non-trivial challenges with respect to forming such high-density semiconductor devices.

### BRIEF DESCRIPTION OF THE DRAWINGS

FIGS. 1A and 1B are cross-sectional views that illustrate a portion of a gate trench (FIG. 1A) and a source/drain trench (FIG. 1B) of an integrated circuit with a series of dielectric walls formed from the backside of the structure, in accordance with an embodiment of the present disclosure.

FIGS. 2A and 2B are cross-sectional views that illustrate one stage in an example process for forming an integrated circuit with a series of dielectric walls formed from the backside of the structure, in accordance with an embodiment of the present disclosure.

FIGS. 3A and 3B are cross-sectional views that illustrate another stage in the example process for forming an integrated circuit with a series of dielectric walls formed from the backside of the structure, in accordance with an embodiment of the present disclosure.

FIGS. 4A and 4B are cross-sectional views that illustrate another stage in the example process for forming an integrated circuit with a series of dielectric walls formed from the backside of the structure, in accordance with an embodiment of the present disclosure.

FIGS. 5A and 5B are cross-sectional views that illustrate another stage in the example process for forming an integrated circuit with a series of dielectric walls formed from the backside of the structure, in accordance with an embodiment of the present disclosure.

FIGS. 6A and 6B are cross-sectional views that illustrate another stage in the example process for forming an integrated circuit with a series of dielectric walls formed from the backside of the structure, in accordance with an embodiment of the present disclosure.

FIGS. 7A and 7B are cross-sectional views that illustrate another stage in the example process for forming an integrated circuit with a series of dielectric walls formed from the backside of the structure, in accordance with an embodiment of the present disclosure.

FIGS. 8A and 8B are cross-sectional views that illustrate another stage in the example process for forming an integrated circuit with a series of dielectric walls formed from the backside of the structure, in accordance with an embodiment of the present disclosure.

FIGS. 9A and 9B are cross-sectional views that illustrate another stage in the example process for forming an integrated circuit with a series of dielectric walls formed from the backside of the structure, in accordance with an embodiment of the present disclosure.

FIGS. 10A and 10B are cross-sectional views that illustrate another stage in the example process for forming an integrated circuit with a series of dielectric walls formed from the backside of the structure, in accordance with an embodiment of the present disclosure.

FIGS. 11A and 11B are cross-sectional views that illustrate another stage in the example process for forming an integrated circuit with a series of dielectric walls formed from the backside of the structure, in accordance with an embodiment of the present disclosure.

FIGS. 12A and 12B are cross-sectional views that illustrate another stage in the example process for forming an integrated circuit with a series of dielectric walls formed from the backside of the structure, in accordance with an embodiment of the present disclosure.

FIGS. 13A and 13B are cross-sectional views that illustrate another stage in the example process for forming an integrated circuit with a series of dielectric walls formed from the backside of the structure, in accordance with an embodiment of the present disclosure.

FIGS. 14A and 14B are cross-sectional views that illustrate another stage in the example process for forming an integrated circuit with a series of dielectric walls formed from the backside of the structure, in accordance with an embodiment of the present disclosure.

FIGS. 15A and 15B are cross-sectional views that illustrate another stage in the example process for forming an integrated circuit with a series of dielectric walls formed from the backside of the structure, in accordance with an embodiment of the present disclosure.

FIGS. 16A and 16B are cross-sectional views that illustrate another stage in the example process for forming an integrated circuit with a series of dielectric walls formed from the backside of the structure, in accordance with an embodiment of the present disclosure.

FIGS. 17A and 17B are cross-sectional views that illustrate another stage in the example process for forming an integrated circuit with a series of dielectric walls formed from the backside of the structure, in accordance with an embodiment of the present disclosure.

FIGS. 18A and 18B are cross-sectional views that illustrate another stage in the example process for forming an integrated circuit with a series of dielectric walls formed from the backside of the structure, in accordance with an embodiment of the present disclosure.

FIGS. 19A and 19B are cross-sectional views that illustrate another stage in the example process for forming an integrated circuit with a series of dielectric walls formed from the backside of the structure, in accordance with an embodiment of the present disclosure.

FIGS. 20A and 20B are cross-sectional views that illustrate another stage in the example process for forming an integrated circuit with a series of dielectric walls formed from the backside of the structure, in accordance with an embodiment of the present disclosure.

FIG. 21 illustrates a cross-section view of a chip package containing one or more semiconductor dies, in accordance with some embodiments of the present disclosure.

FIG. 22 is a flowchart of a fabrication process for semiconductor devices having a series of dielectric walls formed from the backside of the structure, in accordance with an embodiment of the present disclosure.

FIG. 23 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having adjacent pairs of semiconductor devices separated by dielectric walls that are formed from the backside of the structure. The techniques can be used in any number of integrated circuit applications and are particularly useful with respect to logic and memory cells, such as those cells that use finFETs or gate-all-around transistors (e.g., ribbonFETs and nanowire FETs). In an example, neighboring semiconductor devices each include a semiconductor region extending between a source region and a drain region, and a gate structure extending over the semiconductor regions of the neighboring semiconductor devices. A dielectric wall (e.g., a gate cut) may be present between each pair of neighboring semiconductor devices thus interrupting the gate structure and isolating the gate of one semiconductor device from the gate of the other semiconductor device. A number of such dielectric walls may be formed, for example, from the backside of the structure as a series of parallel lines across the integrated circuit, or in one or more regions of the integrated circuit. In an embodiment, a conductive link may extend through a given dielectric wall to electrically connect the adjacent gate electrodes together. Since the dielectric wall is formed from the backside, this conductive link is formed along the bottom of the gate trench rather than along the top of the gate trench. Other conductive links may also be formed through the dielectric wall in the source/drain trench to connect adjacent source or drain contacts. Numerous variations and embodiments will be apparent in light of this disclosure.

### General Overview

As previously noted above, there remain a number of non-trivial challenges with respect to integrated circuit fabrication. In more detail, dielectric walls are sometimes provided between two adjacent semiconductor devices to isolate first and second portions of a gate structure that crosses over each of the adjacent semiconductor devices. Accordingly, a dielectric wall can be used to isolate the gates of two devices from one another. Forming such specifically located structures can require numerous masking and etching processes that are relatively complex to implement and can compromise the integrity of the integrated circuit. Some dielectric walls can extend beyond a single gate trench to isolate multiple pairs of adjacent devices in different gate trenches. Electrically connecting the gates on either side of a given wall can be accomplished with a conductive bridge that passes through the wall. However, additional masking and etching processes used to form such conductive bridges can cause damage to other front-side transistor elements.

Thus, and in accordance with an embodiment of the present disclosure, techniques are provided herein to form a grid of dielectric walls (e.g., series of parallel dielectric walls) across an integrated circuit (or a portion thereof) from the backside of the structure rather than from the frontside. According to some such examples, forming the dielectric walls between each device pair allows for a more streamlined masking and etching process to form the dielectric walls through various material types (e.g., the dielectric walls may be formed after the metal gates are formed). Furthermore, the backside fabrication process for the dielectric walls allows for conductive bridges to be formed through chosen dielectric walls (e.g., to link adjacent gate electrodes in the gate trench or to link adjacent source/drain contacts in the source/drain trench) without risking damage to other frontside transistor structures. According to some embodiments, the dielectric wall between a given pair of adjacent devices may be etched back from the backside of the structure and the backside recess may be plugged with a conductive material to bridge the gap between the adjacent gate structures of the adjacent devices. In this way, the conductive bridge is formed at or near the bottom of the gate trench rather than at or near the top.

According to an embodiment, an integrated circuit includes a first semiconductor device having a first semiconductor region extending in a first direction from a first source or drain region and a first gate electrode around the first semiconductor region, and a second semiconductor device having a second semiconductor region extending in the first direction from a second source or drain region and a second gate electrode around the second semiconductor region. The second semiconductor device is spaced from the first semiconductor device in a second direction different from the first direction. The integrated circuit further includes a dielectric structure (one or more dielectric layers) beneath the first gate electrode and the second gate electrode, a dielectric wall extending along the first direction between the first gate electrode and the second gate electrode and extending in a third direction along at least an entire height of the first gate electrode and the second gate electrode, and a conductive bridge extending through a bottom portion of the dielectric wall along the second direction and contacting the first gate electrode and the second gate electrode. According to an embodiment, the conductive bridge is on a top surface of the dielectric structure.

According to another embodiment, an integrated circuit includes a first semiconductor device having a first semiconductor region extending in a first direction from a first source or drain region and a first gate electrode around the first semiconductor region, and a second semiconductor device having a second semiconductor region extending in the first direction from a second source or drain region and a second gate electrode around the second semiconductor region. The second semiconductor device is spaced from the first semiconductor device in a second direction different from the first direction. The integrated circuit further includes a first topside contact on a top surface of the first source or drain region and a second topside contact on a top surface of the second source or drain region, a first bottom contact on a bottom surface of the first source or drain region and a second bottom contact on a bottom surface of the second source or drain region, a dielectric wall extending along the first direction between the first gate electrode and the second gate electrode and between the first source or drain region and the second source or drain region, a first conductive bridge extending through a bottom portion of the dielectric wall along the second direction and contacting the first bottom contact and the second bottom contact, and a second conductive bridge extending through a top portion of the dielectric wall along the second direction and contacting the first topside contact and the second topside contact.

According to another embodiment, an electronic device includes a chip package having one or more dies. At least one of the one or more dies includes a first semiconductor region extending in a first direction from a first source or drain region, a second semiconductor region extending in the first direction from a second source or drain region where the second semiconductor region is spaced from the first semiconductor region in a second direction different from the first direction, a gate electrode around each of the first semiconductor region and the second semiconductor region, a dielectric structure (one or more dielectric layers) beneath the gate electrode, and a dielectric wall between the first semiconductor region and the second semiconductor region. A portion of the gate electrode extends through a bottom portion of the dielectric wall along the second direction, such that the portion of the gate electrode is on a top surface of the dielectric structure.

According to another embodiment, a method of forming an integrated circuit includes forming a first fin comprising first semiconductor material and a second fin comprising second semiconductor material, the first and second fins extending above a substrate and each extending parallel to each other in a first direction; forming a first source or drain region at an end of the first fin and a second source or drain region at an end of the second fin; forming a gate electrode extending over the first fin and the second fin in a second direction different from the first direction; removing the substrate from a backside of the integrated circuit; after removing the substrate, forming a recess through an entire thickness of the gate electrode from the backside between the first semiconductor material and the second semiconductor material, the recess further extending in the first direction between the first source or drain region and the second source or drain region; forming a dielectric material within the recess; recessing a portion of the dielectric material between the first semiconductor material and the second semiconductor material; forming a conductive material on the dielectric material, the conductive material being within the recess and contacting the gate electrode; and forming a dielectric layer on the conductive material.

The techniques can be used with any type of non-planar transistors, including finFETs (sometimes called double-gate transistors, or tri-gate transistors), or nanowire, nanosheet, and nanoribbon transistors (sometimes called gate-all-around transistors), to name a few examples. The source and drain regions can be, for example, epitaxial regions that are deposited during an etch-and-replace source/drain forming process. The dopant-type in the source and drain regions will depend on the polarity of the corresponding transistor. The source and drain regions may be any epitaxial diffusion region. The gate structure can be implemented with a gate-first process or a gate-last process (sometimes called a remove metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of dielectric walls between every adjacent pair of semiconductor devices of a given integrated circuit along with one or more gate links or conductive bridges at or near the bottom of the gate trench between gate structures of one or more adjacent semiconductor devices. In some other examples, conductive bridges may be observed extending through dielectric walls between adjacent source/drain contacts within the source/drain trenches. Such conductive bridges may form connections between either topside source/drain contacts, backside source/drain contacts, or both topside and backside source/drain contacts of a given adjacent pair of source or drain regions. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer. A structure may include one or more layers. In some cases, the one or more layers of a given structure may all be the same electrical type of material (e.g., dielectric material, or conductive material, or semiconductor material), although other example structures may have a hybrid configuration (mix of dielectric and conductive materials, like a gate structure). In some cases, the one or more layers of a given structure may be the same electrical type but compositionally different material (e.g., a first layer of low-k dielectric material, and a second layer of high-k dielectric material). The layers of a given structure may be arranged in a vertical fashion (one layer stacked on another layer), and/or a horizontal fashion (one layer laterally adjacent to another layer).

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

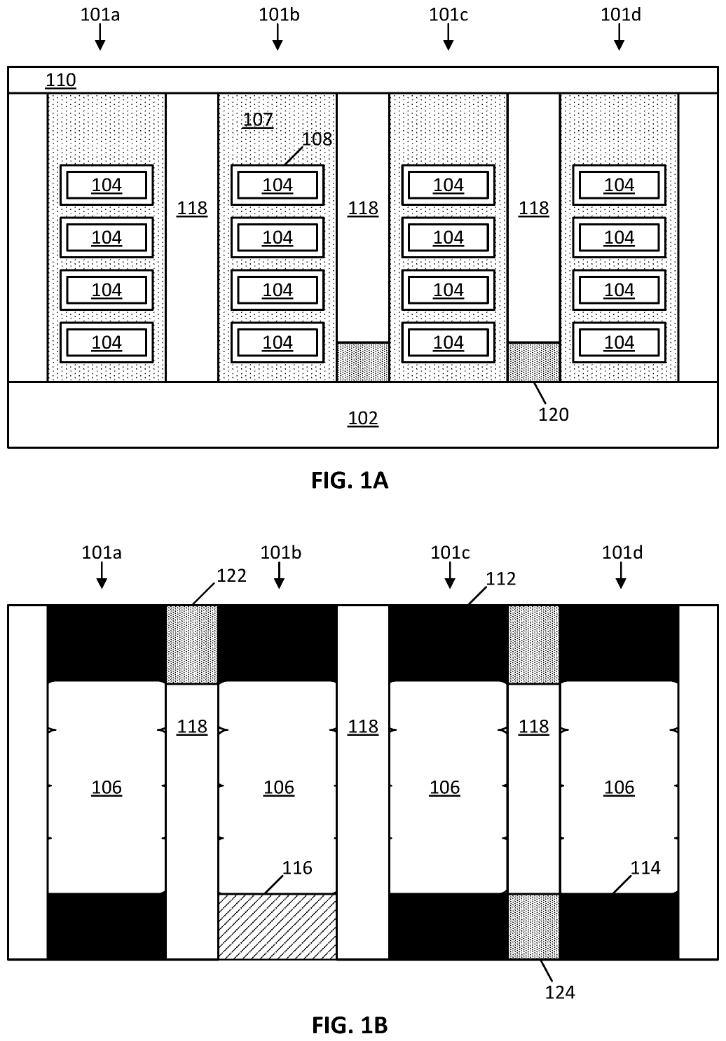

FIGS. 1A and 1B illustrate cross-section views taken across the gate trench (FIG. 1A) and adjacent source/drain trench (FIG. 1B) of a plurality of semiconductor devices 101a-101d, according to some embodiments. Each of semiconductor devices 101a-101d may be non-planar metal oxide semiconductor (MOS) transistors, such as tri-gate or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions).

As can be seen, semiconductor devices 101a-101d are formed over a base dielectric structure 102. Any number of semiconductor devices can be formed on or over base dielectric structure 102, but four are used here as an example. According to some embodiments, base dielectric structure 102 represents any number of dielectric layers on the backside of the semiconductor devices that may be formed following the removal of a substate from the backside of the structure. In some cases, dielectric structure 102 is a single layer of dielectric material. In other example cases, dielectric structure 102 includes two or more distinct depositions of dielectric material, wherein each deposition may be the same dielectric material or different dielectric materials. In some such cases, a seam may be visible between the same (or different) dielectric materials that are deposited at different times. The substate can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. As noted above, the substrate may be removed from the backside and replaced with one or more backside interconnect layers (including base dielectric structure 102) to provide backside power and signal routing. Base dielectric structure 102 may include any suitable dielectric material, such as silicon dioxide.

Each semiconductor device includes one or more nanoribbons 104 extending between epitaxial source or drain regions 106 in a first direction (in/out of page). A gate structure that includes a gate electrode 107 and a gate dielectric 108 extend over the one or more nanoribbons 104 in a second direction (left to right on the page, orthogonal to the first direction) to form the transistor gate. It should be noted that the one or more nanoribbons 104 of each device may also be fins in trigate transistor designs.

The semiconductor material used in each of the semiconductor devices may be formed from the semiconductor substrate (which may be subsequently removed as discussed in more detail herein). As noted above, the one or more semiconductor regions of the devices may include fins that can be, for example, native to the substrate (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons (such as the illustrated nanoribbons 104) during a gate forming process where one type of the alternating layers are selectively etched away so as to liberate the other type of alternating layers within the channel region, so that a gate-all-around process can then be carried out. Again, the alternating layers can be blanket deposited and then etched into fins or deposited into fin-shaped trenches.

Source or drain regions 106 may be formed at the ends of the one or more nanoribbons 104 of each device, and thus may be aligned along the second direction from one another within a common source/drain trench, as illustrated in FIG. 1B. Note that FIG. 1B illustrates source or drain regions 106 at first ends of nanoribbons 104 and that similar source or drain regions would be formed at opposite ends of nanoribbons 104 in another source/drain trench on the other side of the gate trench. According to some embodiments, source or drain regions 106 are epitaxial regions that are provided at the ends of the semiconductor regions in an etch-and-replace process. Any semiconductor materials suitable for source or drain regions can be used (e.g., group IV and group III-V semiconductor materials). Source or drain regions 106 may include multiple layers such as liners and capping layers to improve contact resistance. In any such cases, the composition and doping of source or drain regions 106 may be the same or different, depending on the polarity of the transistors. Any number of source or drain configurations and materials can be used.

As noted above, a gate structure extends in the second direction over the one or more nanoribbons 104 of various devices and includes both gate electrode 107 and gate dielectric 108. Gate electrode 107 may include any sufficiently conductive material such as a metal, metal alloy, or doped polysilicon. In some embodiments, gate electrode 107 includes one or more workfunction metals around the one or more semiconductor regions. In some embodiments, p-channel devices include a workfunction metal having titanium around its one or more semiconductor regions and n-channel devices include a workfunction metal having tungsten around its one or more semiconductor regions. Gate electrode 107 may also include a fill metal or other conductive material (e.g., tungsten, ruthenium, molybdenum, or cobalt) around the workfunction metals to provide the whole gate electrode structure. Gate dielectric 108 represents any number of dielectric layers that exist between the one or more nanoribbons 104 and gate electrode 107. In some embodiments, a gate cap 110 extends along a top portion of the gate trench over gate electrode 107. Gate cap 110 may be any suitable dielectric material, such as silicon nitride or silicon oxynitride.

According to some embodiments, one or more topside contacts 112 are provided to make electrical connection with the underlying source or drain region 106. Topside contacts 112 may include any suitable conductive material such as tungsten, ruthenium, molybdenum, or cobalt to name a few examples. In the illustrated example, each source or drain region 106 includes a corresponding topside contact 112. However, in some embodiments, one or more source or drain regions 106 do not include topside contact 112 and may instead have a dielectric material on their top surface. Similarly, any number of source or drain regions 106 may include a backside contact 114 to make electrical connection beneath the corresponding source or drain region 106. Backside contacts 114 may include any suitable conductive material such as tungsten, ruthenium, molybdenum, or cobalt to name a few examples. Any number of source or drain regions 106 may not have a backside contact, and instead there may be a dielectric plug 116 on the bottom surface of the source or drain regions. Dielectric plug 116 can include any suitable dielectric material, such as silicon dioxide.

According to some embodiments, each gate structure is separated along the second direction by a different dielectric wall 118, which act like dielectric barriers between gate structures. The dielectric walls 118 effectively isolate the gate structures from one another to form electrically separate gates for each semiconductor device. In the illustrated example, three dielectric walls 118 are formed. Dielectric walls 118 may be formed from a sufficiently insulating material, such as a dielectric material. Example materials for dielectric walls 118 include silicon nitride, silicon oxide, or silicon oxynitride. In some embodiments, dielectric walls 118 include a dielectric liner and a dielectric fill on the dielectric liner. The dielectric liner may be a high-k dielectric material, such as silicon nitride while the dielectric fill may be a low-k dielectric material such as silicon dioxide or flowable oxide. According to some embodiments, dielectric walls 118 each has a largest width between about 10 nm and about 20 nm.

According to some embodiments, dielectric walls 118 extend in the first direction (along the length of nanoribbons 104) across the gate trench and further along the source/drain trench to isolate adjacent source or drain regions 106 from each other, as illustrated in FIG. 1B. As noted above, dielectric walls 118 separate all gate structures from one another along the second direction. In some applications, two adjacent gate structures may need to be connected. Thus, according to an embodiment, a gate link (e.g., a conductive bridge) 120 connects between adjacent gate electrodes 107 underneath a given dielectric wall 118. Gate link 120 may be any suitable conductive material, and may include the same conductive material as gate electrode 107 (e.g., tungsten, ruthenium, molybdenum, or cobalt). According to some embodiments, only a portion of dielectric wall 118 that extends across the gate trench is recessed from the backside to form gate link 120. As noted above, gate link 120 is formed from the backside of the structure and is thus located at the bottom of the gate trench. In some embodiments, gate link 120 is on a top surface of base dielectric structure 102, which extends beneath the semiconductor devices. In some embodiments, an imaginary plane extending along the first and second directions intersects both gate link 120 and the bottom-most nanoribbon 104 of each of semiconductor devices 101a-101d. In the illustrated example of FIG. 1A, two gate links 120 are provided to connect the gates of each of semiconductor devices 101b, 101c, and 101d.

In a similar fashion to gate link 120, other conductive structures can be provided within the source/drain trench to connect between adjacent source/drain contacts. According to some embodiments, two adjacent frontside contacts 112 can be connected using a frontside contact link 122 (e.g., a conductive bridge) that extends over a given dielectric wall 118. Frontside contact link 122 may be any suitable conductive material, and may include the same conductive material as frontside contacts 112. In the illustrated example of FIG. 1B, frontside contact links 122 are used to connect the frontside source/drain contacts of semiconductor devices 101a and 101b, and to connect the frontside source/drain contacts of semiconductor devices 101c and 101d.

According to some embodiments, two adjacent backside contacts 114 can be connected using a backside contact link 124 (e.g., a conductive bridge) that extends beneath a given dielectric wall 118. Backside contact link 124 may be any suitable conductive material and may include the same conductive material as backside contacts 114. In the illustrated example of FIG. 1B, backside contact links 124 are used to connect the backside source/drain contacts of semiconductor devices 101c and 101d.

It should be noted that the gate links 120, frontside contact links 122, and backside contact links 124 may be present only within their respective gate trench or source/drain trench, such that they do not extend further in the first direction to short gate electrodes with source/drain contacts. For example, gate link 120 between the gates of semiconductor devices 101c and 101d is electrically isolated from backside contact link 124 between the backside contacts of semiconductor devices 101c and 101d, according to some embodiments. According to some embodiments, a seam may be present between any of gate links 120, frontside contact links 122, and backside contact links 124 and the adjacent conductive material of gate electrode 107, frontside contacts 112, or backside contacts 114. In some examples, a seam may not be visible such that the linkages appear to be continuous metal extending either over a given dielectric wall 118 or under a given dielectric wall 118.

### Fabrication Methodology

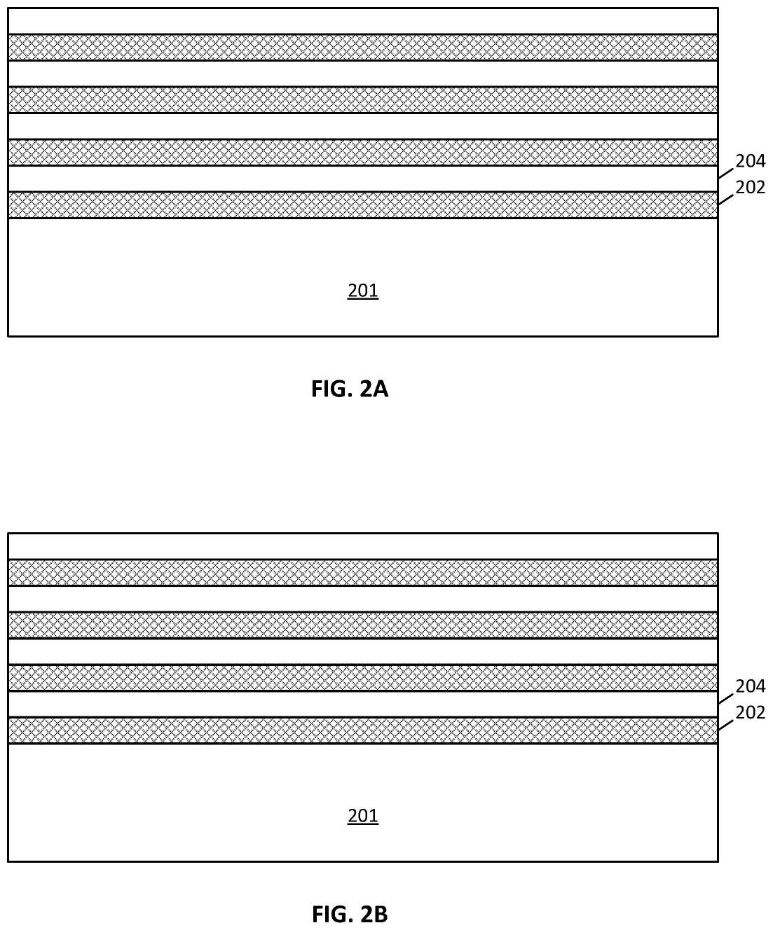

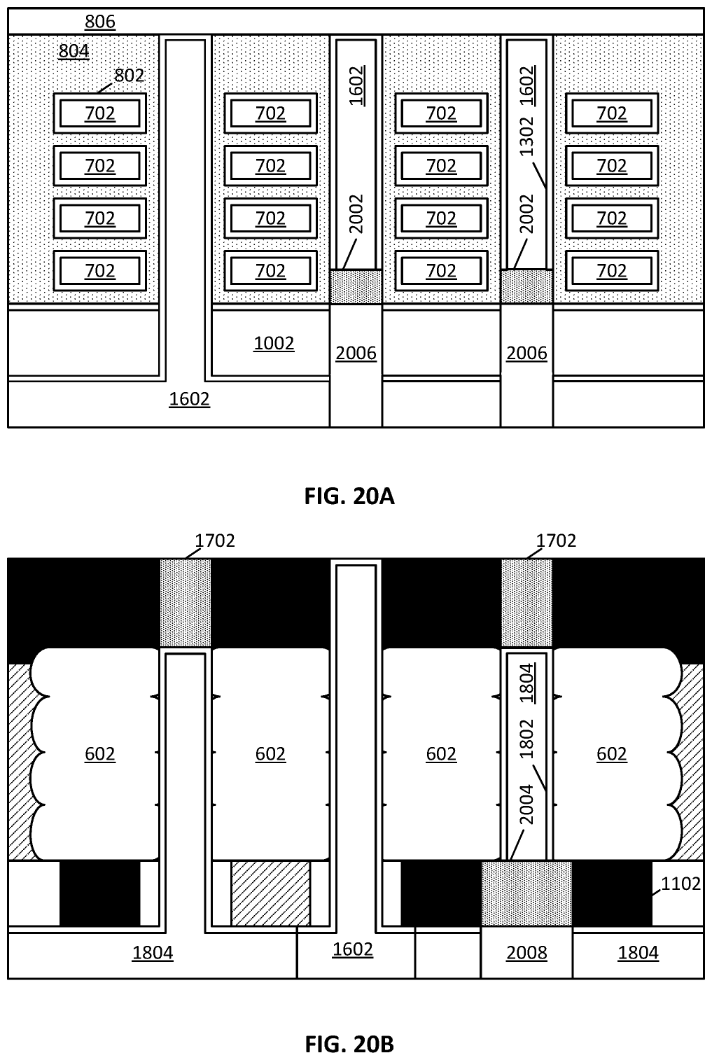

FIGS. 2A-20A and 2B-20B are cross-sectional views that collectively illustrate an example process for forming an integrated circuit configured with a series of dielectric walls formed from the backside of the structure, in accordance with an embodiment of the present disclosure. FIGS. 2A-20A represent cross-sectional views taken across a gate trench of the integrated circuit, while FIGS. 2B-20B represent cross-sectional views taken across the source/drain trench adjacent to the gate trench along the same direction. Each figure shows an example structure that results from the process flow up to that point in time, so the depicted structure evolves as the process flow continues, culminating in the structure shown in FIGS. 20A and 20B, which is similar to the structure shown in FIGS. 1A and 1B, respectively. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated. Figures sharing the same number (e.g., FIGS. 2A and 2B) illustrate different views of the structure at the same point in time during the process flow.

FIGS. 2A and 2B illustrate parallel cross-sectional views taken through a stack of alternating semiconductor layers on a semiconductor substrate 201. FIG. 2A is taken across a portion of the stack that will eventually become a gate trench while FIG. 2B is taken across a portion of the stack that will eventually become a source/drain trench adjacent and parallel to the gate trench. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Thickness here refers to the vertical direction or up and down the page of FIGS. 2A-B. Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

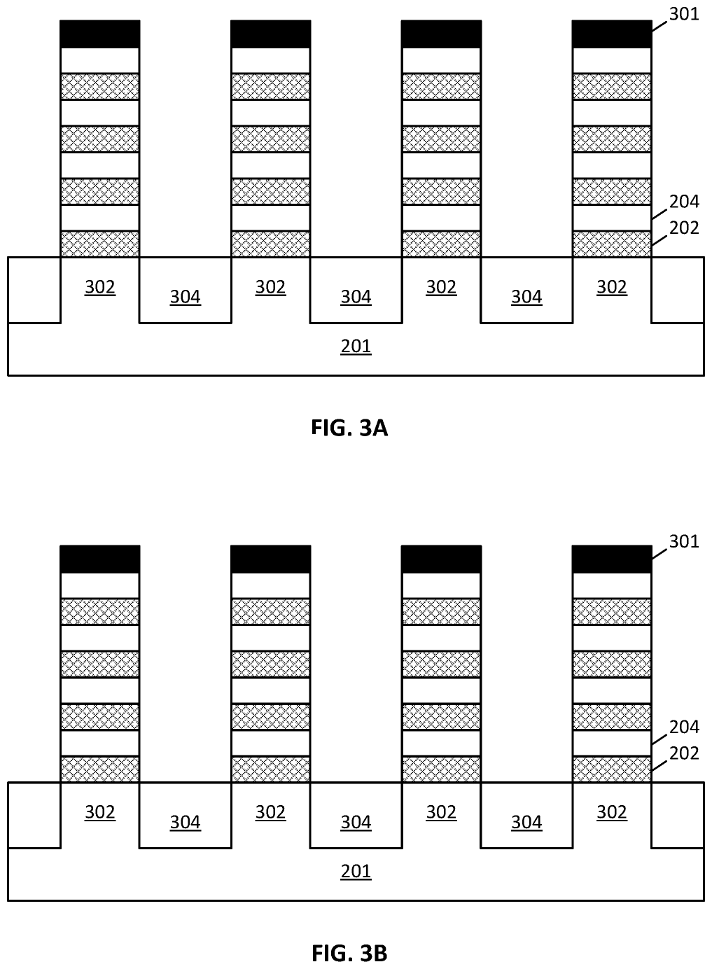

FIGS. 3A and 3B depict the cross-section views of the structure shown in FIGS. 2A and 2B, respectively, following the formation of a cap layer 301 and the subsequent formation of fins beneath cap layer 301, according to an embodiment. Cap layer 301 may be any suitable hard mask material such as a carbon hard mask (CHM) or silicon nitride. Cap layer 301 is patterned into rows to form corresponding rows of fins from the alternating layer stack of sacrificial layers 202 and semiconductor layers 204. The rows of fins extend lengthwise in a first direction (e.g., into and out of the page of each cross-section view).

According to some embodiments, an anisotropic etching process through the layer stack continues into at least a portion of substrate 201, where the unetched portions of substrate 201 beneath the fins form subfin regions 302. The etched portions of substrate 201 may be filled with a dielectric fill 304 that acts as shallow trench isolation (STI) between adjacent fins. Dielectric fill 304 may be any suitable dielectric material such as silicon oxide, and may be recessed to a desired depth as shown (in this example case, down to around the upper surface of subfin regions 302), so as to define the active portion of the fins that will be covered by a gate structure.

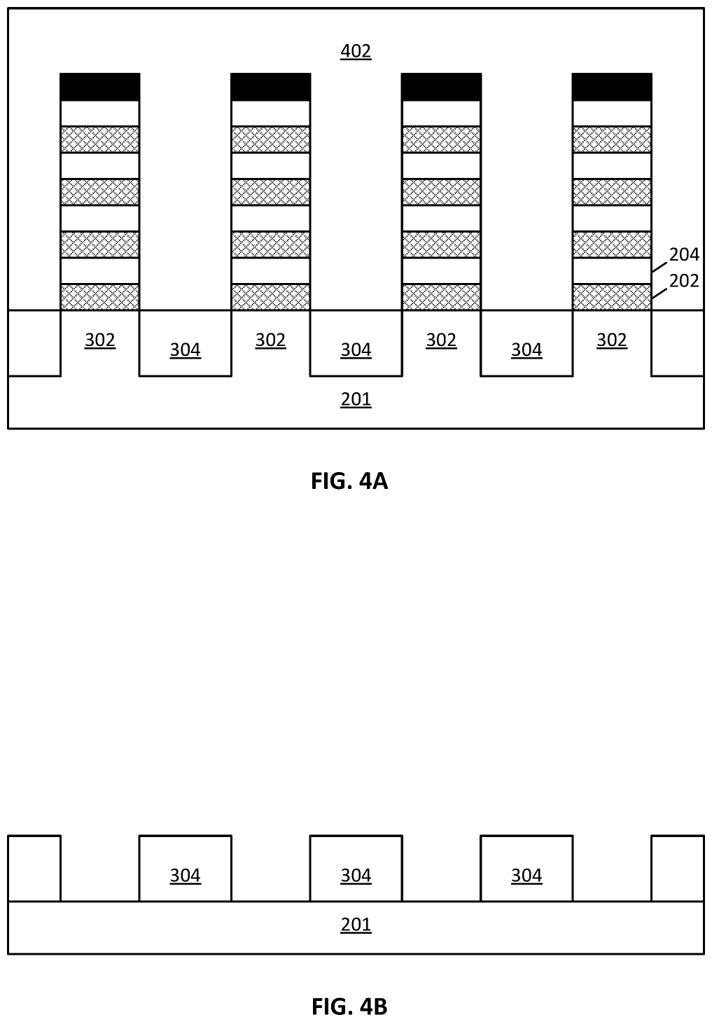

FIGS. 4A and 4B depict the cross-section views of the structure shown in FIGS. 3A and 3B, respectively, following the formation of a sacrificial gate 402 extending across the fins in a second direction different from the first direction, according to some embodiments. Sacrificial gate 402 may extend across the fins in a second direction that is orthogonal to the first direction. According to some embodiments, the sacrificial gate material is formed in parallel strips across the integrated circuit and removed in all areas not protected by a gate masking layer. Sacrificial gate 402 may be any suitable material that can be selectively removed without damaging the semiconductor material of the fins. In some examples, sacrificial gate 402 includes polysilicon.

As seen in the cross-section views, sacrificial gate 402 extends across the fins along the gate trench cross-section of FIG. 4A but is not present along the source/drain trench cross-section of FIG. 4B. Accordingly, sacrificial gate 402 (along with any gate spacers formed on the sidewalls of sacrificial gate 402) protect the underlying portions of the fins while the exposed portions of the fins are etched away as seen in FIG. 4B. According to some embodiments, both semiconductor layers 204 and sacrificial layers 202 are etched at substantially the same rate using an anisotropic RIE process. As observed in FIG. 4B, the RIE process removes both the fins and subfins 302 above substrate 201. In some embodiments, the RIE process recesses subfin regions 302 beneath a top surface of dielectric fill 304.

According to some embodiments, the exposed portions of sacrificial layers 202 along the edges of the gate spacers may be recessed and the recesses can be filled with internal spacer material. The internal spacer material may be conformally deposited over the exposed ends of the fins and then etched back to fill the recesses with internal spacers while exposing the ends of semiconductor layers 204.

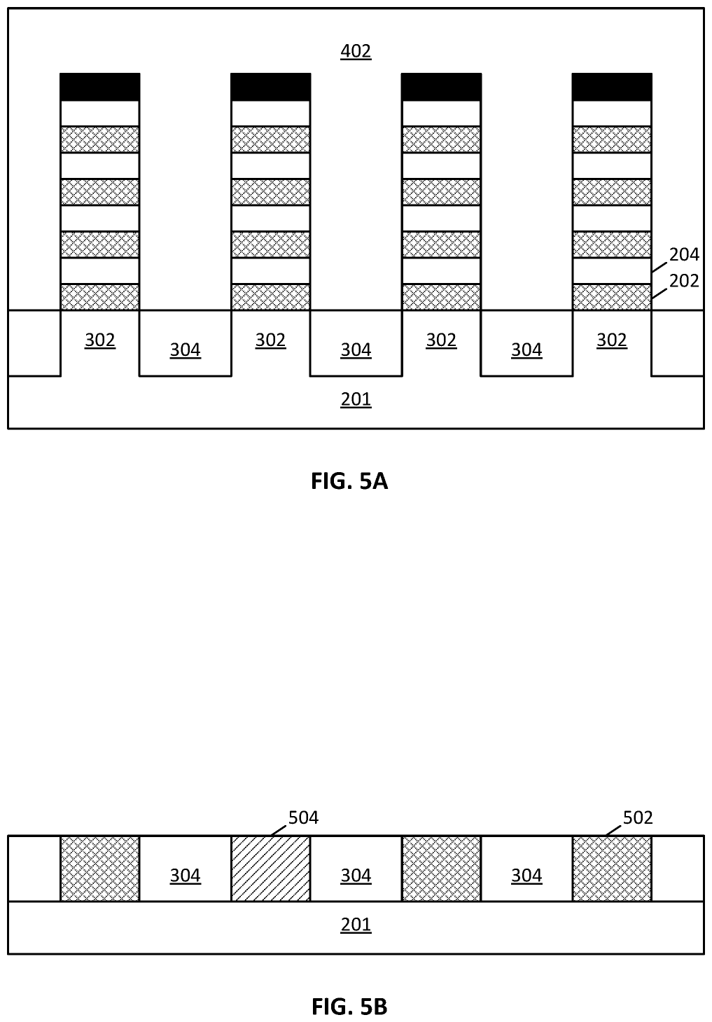

FIGS. 5A and 5B depict the cross-section views of the structure shown in FIGS. 4A and 4B, respectively, following the formation of sacrificial material 502 within the source/drain trench, according to some embodiments. The source/drain trench may be filled with sacrificial material 502, according to some embodiments. Sacrificial material 502 may be any suitable material that can be easily removed at a later time without damaging any surrounding structures. In some examples, sacrificial material 502 includes titanium nitride or aluminum oxide. After deposition of sacrificial material 502, it may be recessed to a final thickness such that a top surface of sacrificial material 502 is substantially coplanar (e.g., within 2 nm) of a top surface of dielectric fill 304.

According to some embodiments, sacrificial material 502 is located in areas where a backside contact to a corresponding source drain is desired. It may be preferable to not have a backside contact to one or more source or drain regions. Thus, according to some embodiments, one or more of the plugs of sacrificial material at the bottom of the source/drain trench may be removed and replaced with a dielectric plug 504. Dielectric plug 504 may be any suitable dielectric material, such as silicon dioxide. In some examples, dielectric plug 504 has the same material composition as the adjacent dielectric fill 304.

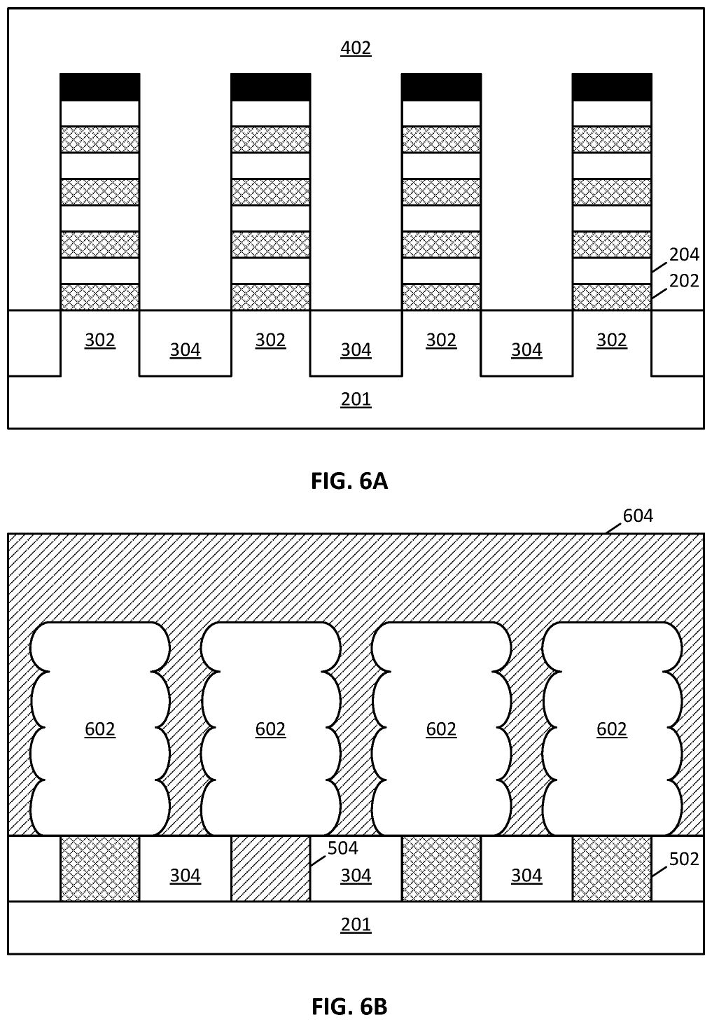

FIGS. 6A and 6B depict the cross-section views of the structure shown in FIGS. 5A and 5B, respectively, following the formation of source or drain regions 602 at the ends of each of the fins (extending into and out of the page in FIG. 6A), according to some embodiments. Source or drain regions 602 may be epitaxially grown from the exposed ends of semiconductor layers 204, such that the material grows together or otherwise merges towards the middle of the source/drain trenches between fins, according to some embodiments. Note that epitaxial growth on one semiconductor layer 204 can fully or partially merge with epitaxial growth on one or more other semiconductor layers 204 in the same vertical stack. The degree of any such merging can vary from one embodiment to the next. In the example of a PMOS device, a given source or drain region 602 may be a semiconductor material (e.g., group IV or group III-V semiconductor materials) having a higher dopant concentration of p-type dopants compared to n-type dopants. In the example of an NMOS device, a given source or drain region 602 may be a semiconductor material (e.g., group IV or group III-V semiconductor materials) having a higher dopant concentration of n-type dopants compared to p-type dopants. According to some embodiments, the various source or drain regions 602 grown from different semiconductor devices may be aligned along the second direction as shown in FIG. 6B. Source or drain regions 602 may be formed directly on sacrificial material 502 and/or dielectric plugs 504.

According to some embodiments, a dielectric fill 604 is provided within the source/drain trench and around source or drain regions 602. Dielectric fill 604 may extend between adjacent ones of the source or drain regions 602 along the second direction and also may extend up and over each of the source or drain regions 602, according to some embodiments. Accordingly, each source or drain region 602 may be isolated from any adjacent source or drain regions 602 by dielectric fill 604. Dielectric fill 604 may be any suitable dielectric material, although in some embodiments, dielectric fill 604 includes the same dielectric material as dielectric fill 304. In one example, both dielectric fill 604 and dielectric fill 304 include silicon dioxide. According to some embodiments, a top surface of dielectric fill 604 may be polished using, for example, chemical mechanical polishing (CMP). The top surface of dielectric fill 604 may be polished until it is substantially coplanar with a top surface of sacrificial gate 402.

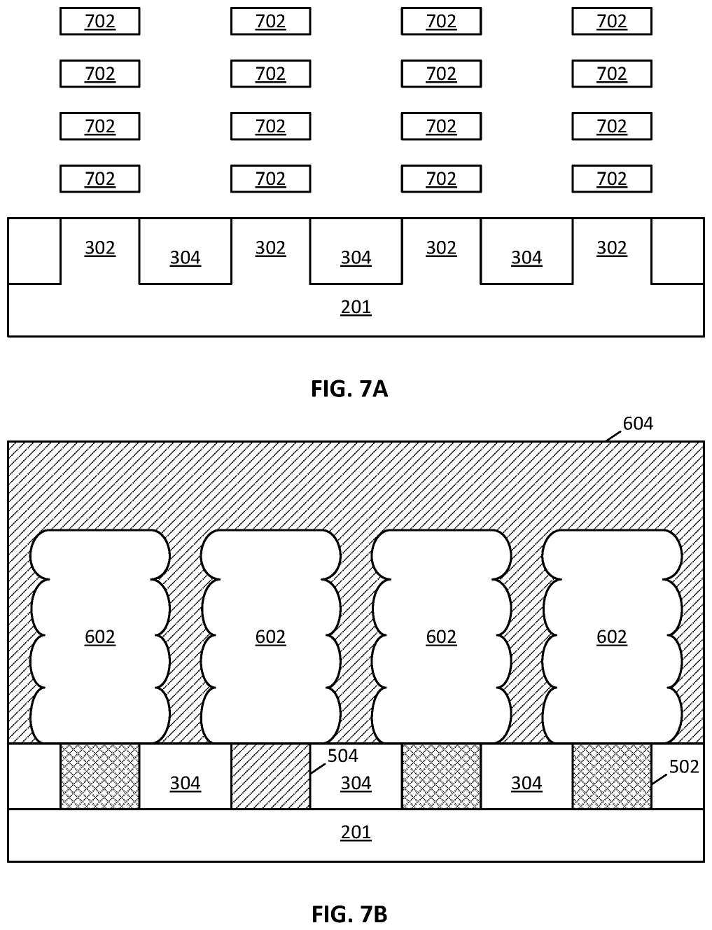

FIGS. 7A and 7B depict the cross-section views of the structure shown in FIGS. 6A and 6B, respectively, following the formation of nanoribbons 702 from semiconductor layers 204, according to some embodiments. Depending on the dimensions of the structures, nanoribbons 702 may also be considered nanowires or nanosheets. Sacrificial gate 402 may be removed using any wet or dry isotropic process thus exposing the alternating layer stack of the fins within the trenches left behind after the removal of sacrificial gate 402. Once sacrificial gate 402 is removed, sacrificial layers 202 may also be removed using a selective isotropic etching process that removes the material of sacrificial layers 202 but does not remove (or removes very little of) semiconductor layers 204 or any other exposed layers (e.g., inner gate spacers). Sacrificial gate 402 and sacrificial layers 202 may be removed together using the same isotropic etching process. At this point, the suspended (sometimes called released) semiconductor layers 204 form nanoribbons 702 that extend in the first direction (into and out of the page) between corresponding source or drain regions 602 and other source or drain regions on the opposite ends of nanoribbons 702.

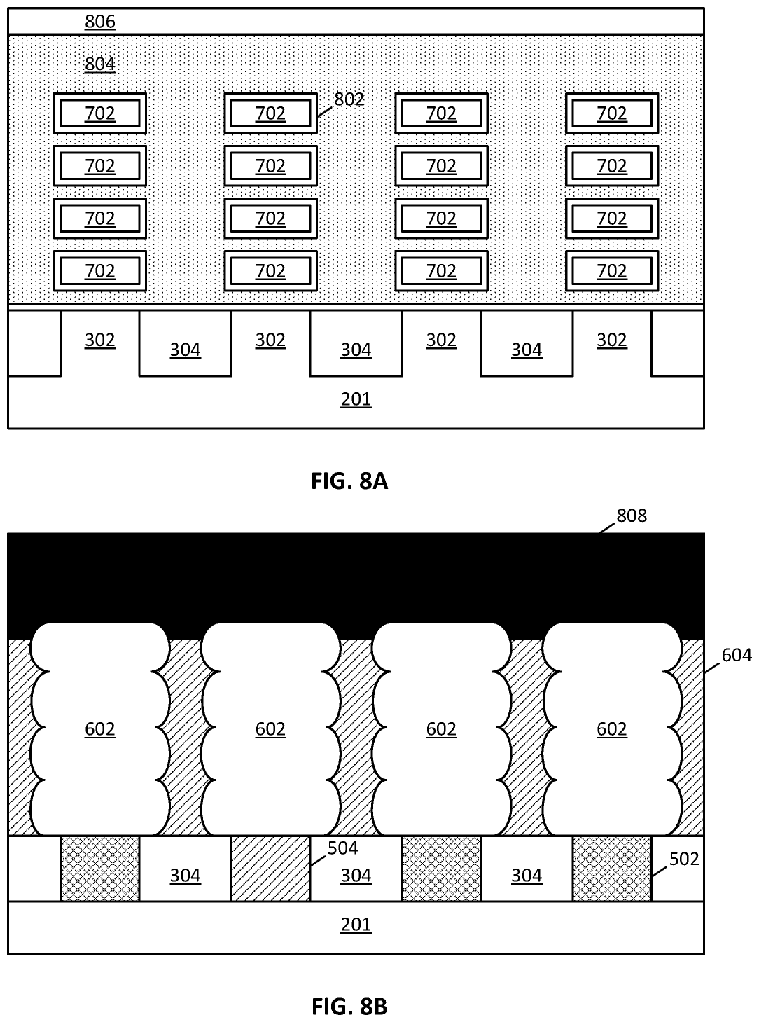

FIGS. 8A and 8B depict the cross-section views of the structure shown in FIGS. 7A and 7B, respectively, following the formation of a gate structure around nanoribbons 702 within the gate trench, according to some embodiments. As noted above, the gate structure includes a gate dielectric 802 and a gate electrode 804. Gate dielectric 802 may be conformally deposited around nanoribbons 702 using any suitable deposition process, such as atomic layer deposition (ALD). Gate dielectric 802 may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 802 is hafnium oxide with a thickness between about 1 nm and about 5 nm. In some embodiments, gate dielectric 802 may include one or more silicates (e.g., titanium silicate, tungsten silicate, niobium silicate, and silicates of other transition metals). Gate dielectric 802 may be a multilayer structure, in some examples. For instance, gate dielectric 802 may include a first layer on nanoribbons 702, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on gate dielectric 802 to improve its quality when a high-k dielectric material is used. In some embodiments, the high-k material can be nitridized to improve its aging resistance. Gate dielectric 802 may form on all exposed surfaces within the gate trench, including on the bottom of the gate trench (e.g., on the top surfaces of subfin portions 302 and dielectric fill 304).

Gate electrode 804 may be deposited on gate dielectric 802 and can be any standard or proprietary conductive structure. In some embodiments, gate electrode 804 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 804 may include, for instance, one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

According to some embodiments, a top portion of gate electrode 804 is recessed within the gate trench and the recess is filled with a dielectric material to form a gate cap 806. Gate cap 806 may be any suitable dielectric material, such as silicon nitride.

According to some embodiments, a topside conductive contact 808 is formed within the source/drain trench and on an upper surface of source or drain regions 602, according to some embodiments. A top portion of dielectric fill 604 may first be recessed until at least a top surface of source or drain regions 602 is exposed. Then, topside conductive contact 808 may be formed within the recessed volume above source or drain regions 602.

Topside conductive contact 808 may include any suitably conductive material such as tungsten, ruthenium, cobalt, titanium, tantalum, molybdenum, or any alloys thereof. A top surface of topside conductive contact 808 may be polished to be substantially coplanar with a top surface of gate cap 806. Note that topside conductive contact 808 may be split into separate isolated contacts over corresponding source or drain regions 602 using dielectric walls as will be described in more detail herein.

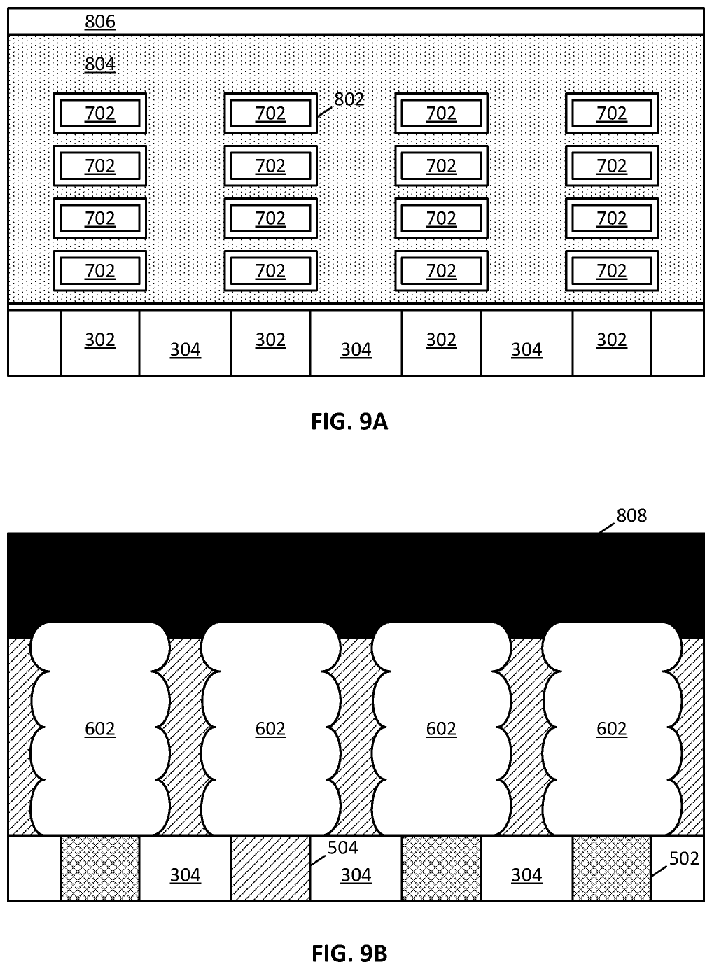

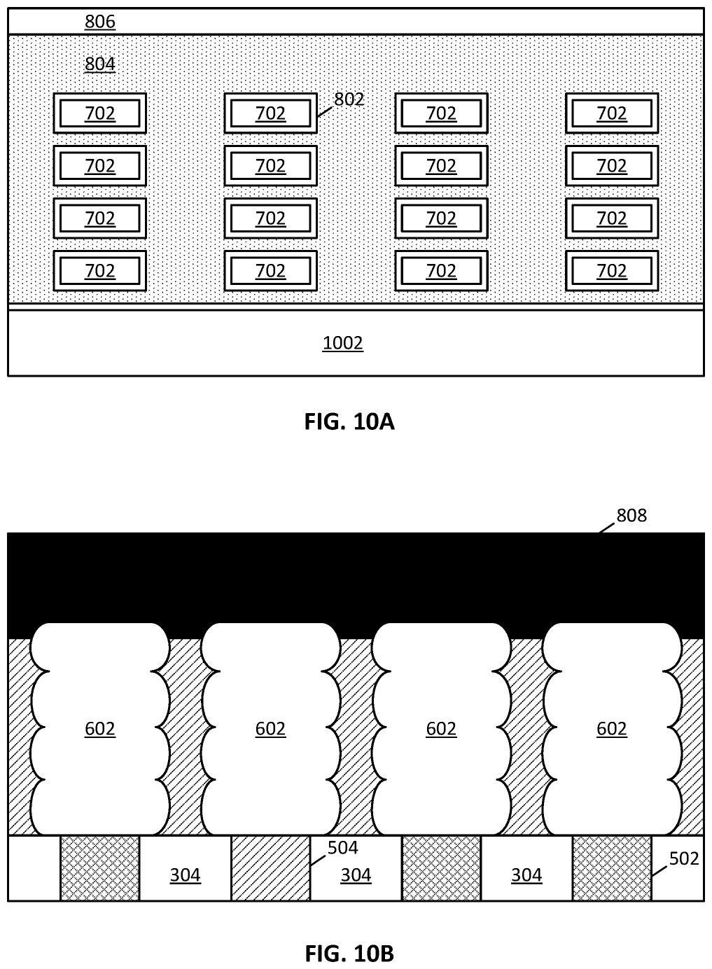

FIGS. 9A and 9B depict the cross-section views of the structure shown in FIGS. 10A and 10B, respectively, following the backside removal of substrate 201, according to some embodiments. Substrate 201 may be polished away via CMP or another grinding process to remove the substrate material. According to some embodiments, substrate 201 continues to be thinned away at least until sacrificial material 502 is exposed from the backside in the source/drain trench. In some examples, portions of subfin regions 302 and/or dielectric fill 304 may also be exposed from the backside in the gate trench.

FIGS. 10A and 10B depict the cross-section views of the structure shown in FIGS. 9A and 9B, respectively, following the backside removal of subfin regions 302 and formation of a base dielectric structure 1002, according to some embodiments. The exposed subfin regions 302 may be removed using a suitable isotropic semiconductor etching process, or any other suitable semiconductor etching process. The backside cavities left behind from the removal of subfin regions 302 may be filled with another dielectric material, such as the same dielectric material as dielectric fill 304. Accordingly, base dielectric structure 1002 may represent the combined dielectric structures of dielectric fill 304 and adjacent dielectric material. In some embodiments, dielectric fill 304 is also removed from the backside following a dielectric etching process and a new dielectric layer is formed on the backside to form base dielectric structure 1002. In any case, the newly deposited dielectric material on the backside of the structure may be polished to expose the bottom surfaces of at least sacrificial material 502 and dielectric plug 504 (if present).

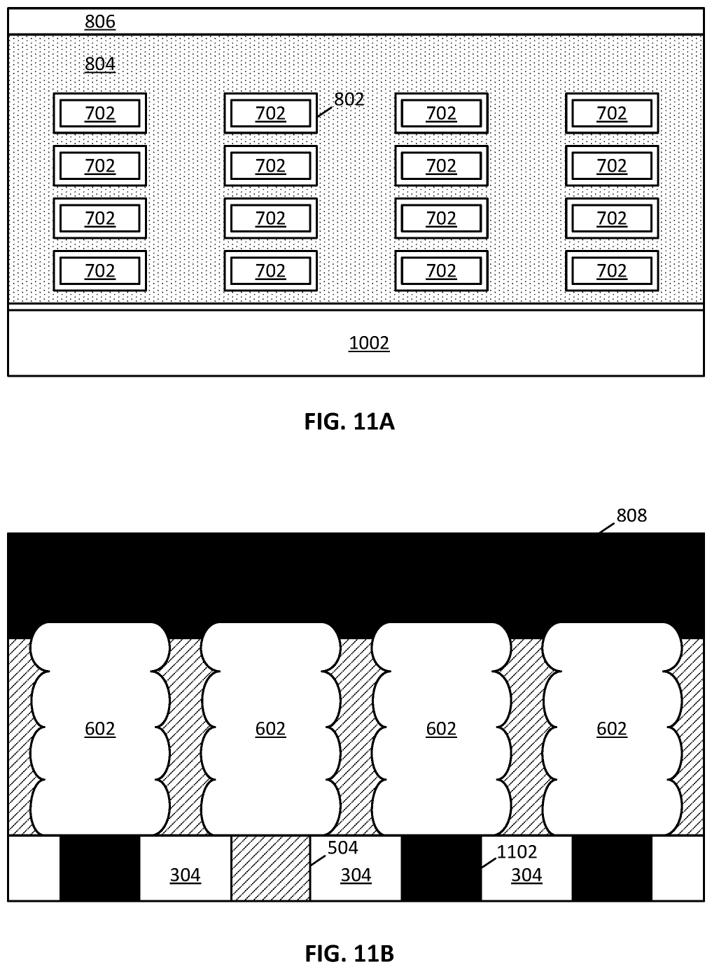

FIGS. 11A and 11B depict the cross-section views of the structure shown in FIGS. 10A and 10B, respectively, following the replacement of sacrificial material 502 with backside contacts 1102, according to some embodiments. Sacrificial material 502 may be selectively removed using any suitable isotropic etching process. Backside contacts 1102 may include any of the same materials discussed above for topside conductive contact 808 and may be the same conductive material(s) as topside conductive contact 808. Backside contacts 1102 directly abut an underside of corresponding source or drain regions 602. The bottom surface of backside contacts 1102 may be polished to be substantially coplanar with the bottom surface of base dielectric structure 1002 and dielectric plug 504 (if present).

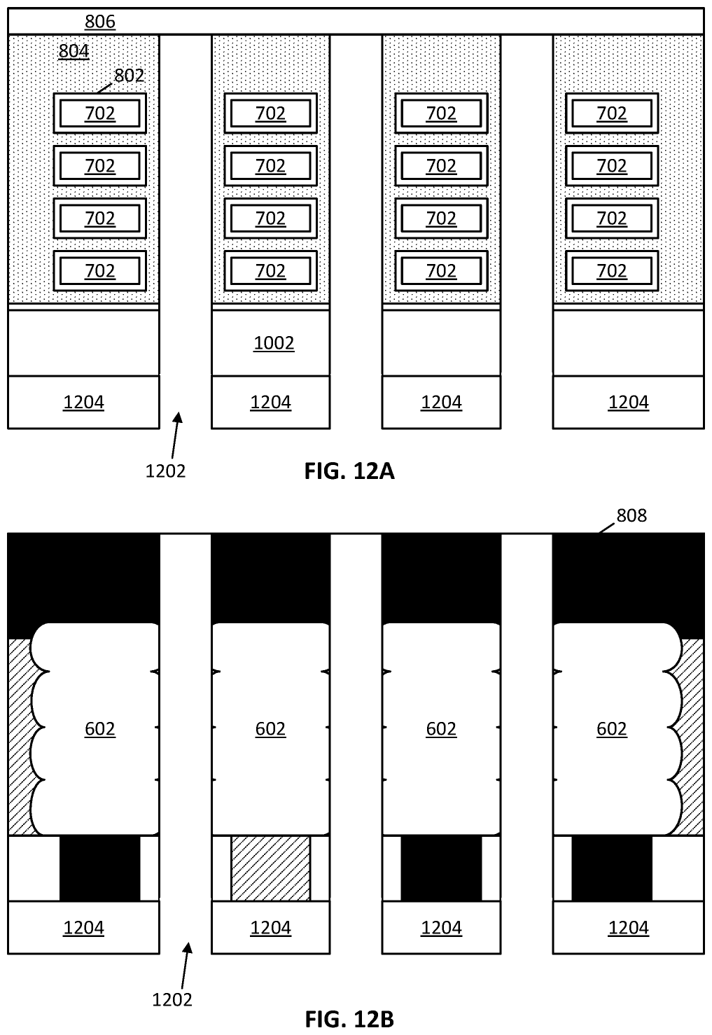

FIGS. 12A and 12B depict the cross-section views of the structure shown in FIGS. 11A and 11B, respectively, following the formation of backside trench recess 1202, according to some embodiments. According to some embodiments, a mask structure 1204 may be formed on the backside of the structure and lithographically patterned to form trench openings through the mask structure 1204 at locations where backside trench recess 1202 are to be formed. An RIE process may be used to etch through the exposed material not protected by mask structure 1204. According to some embodiments, backside trench recesses 1202 are formed through an entire thickness of base dielectric structure 1002 and through an entire thickness of the gate structure within the gate trench. Within the source/drain trench, backside trench recesses 1202 separate adjacent source or drain regions 602 while also etching through the conductive material of topside conductive contacts 808 to isolate adjacent topside conductive contacts 808 over corresponding source or drain regions 602. Backside trench recesses 1202 may have a high height-to-width aspect ratio (e.g., aspect ratio of 5:1 or higher, or 10:1 or higher).

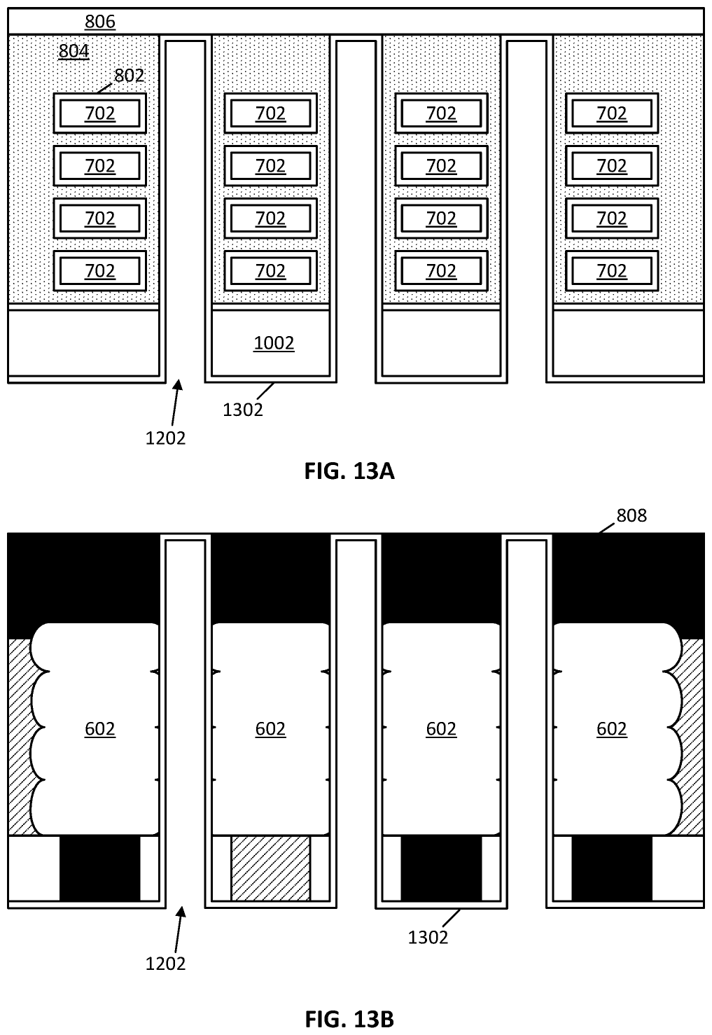

FIGS. 13A and 13B depict the cross-section views of the structure shown in FIGS. 12A and 12B, respectively, following the formation of a dielectric liner 1302, according to some embodiments. Dielectric liner 1302 may be formed on all surfaces of backside trench recesses 1202. Dielectric liner 1302 may include any suitable dielectric material. In some examples, dielectric liner 1302 includes a high-k dielectric material such as silicon nitride, aluminum oxide, or hafnium oxide. The dielectric liner 1302 can be deposited, for instance, via CVD or ALD to provide a relatively thin (e.g., 1 nm to 6 nm thick) conformal layer.

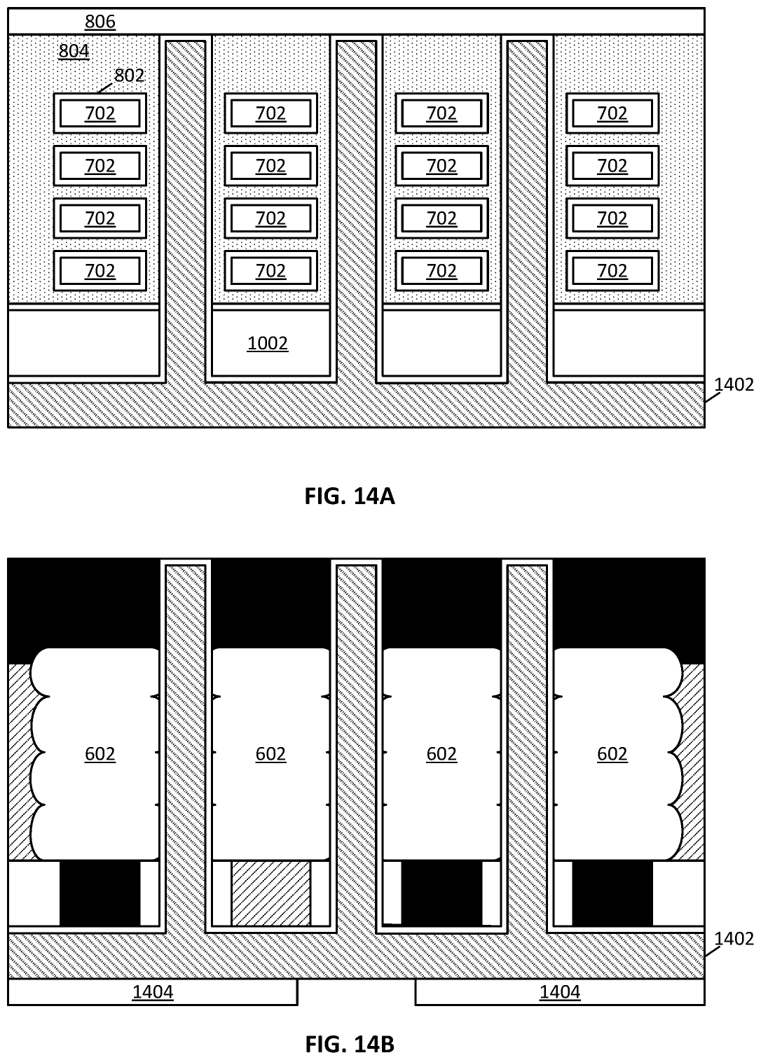

FIGS. 14A and 14B depict the cross-section views of the structure shown in FIGS. 13A and 13B, respectively, following the formation of a masking material 1402, according to some embodiments. Masking material 1402 may be any suitable sacrificial material that can be removed at a later time without damaging the surrounding materials. In some examples, masking material 1402 is carbon hard mask (CHM). Masking material 1402 may be formed within all backside trench recesses 1202 and on dielectric liner 1302. According to some embodiments, a further backside mask structure 1404 is formed on the bottom surface of masking material 1402 and patterned to provide an opening through backside mask structure 1404 over a region where masking material 1402 is to be removed. Backside mask structure 1404 may include any suitable hard mask material or photoresist that is selective to subsequent etching that selectively removes the unmasked portion of masking material 1402.

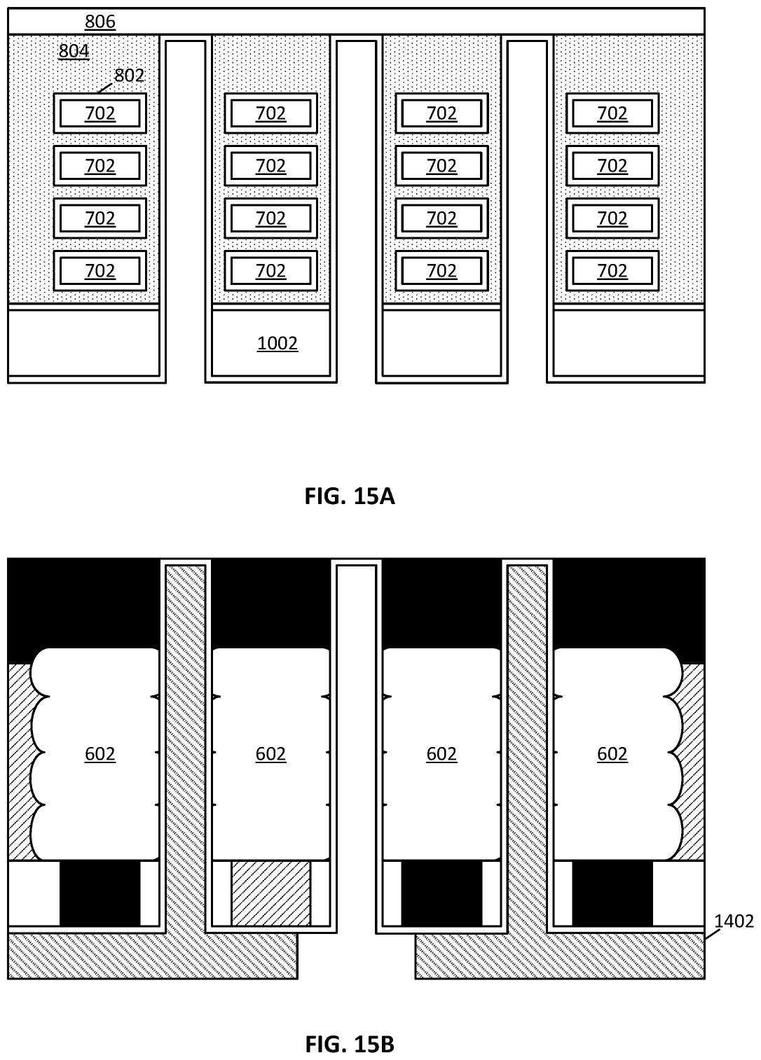

FIGS. 15A and 15B depict the cross-section views of the structure shown in FIGS. 14A and 14B, respectively, following the removal of masking material 1402 from all areas not protected by backside mask structure 1404, according to some embodiments. In some examples, masking material 1402 is removed from all portions of the backside trench recesses 1202 within the gate trenches (as shown in FIG. 15A) and may be removed from one or more of the portions of the backside trench recesses 1202 within the source/drain trenches (as shown in FIG. 15B). The exposed portions of masking material 1402 may be removed using any suitable isotropic etching process. Backside mask structure 1404 may be removed (e.g., via an ashing process, for cases where mask structure 1404 is CHM) following the removal of the exposed portions of masking material 1402.

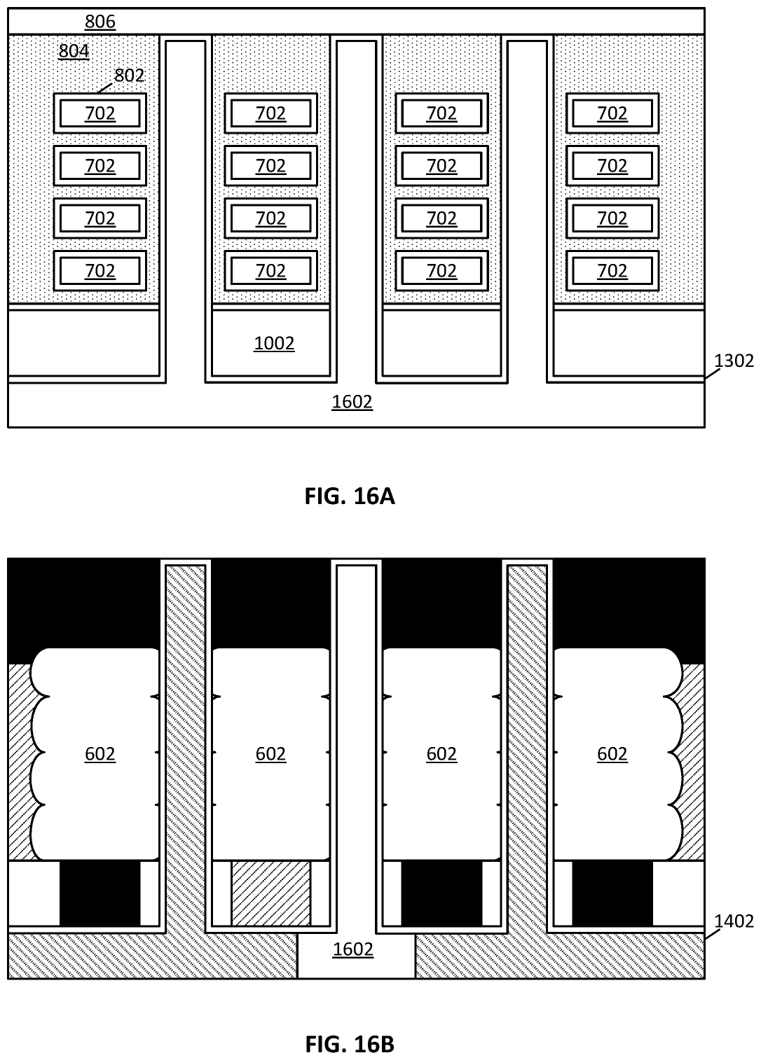

FIGS. 16A and 16B depict the cross-section views of the structure shown in FIGS. 15A and 15B, respectively, following the formation of a dielectric fill 1602 within any exposed backside trench recesses 1202 (e.g., any that are not filled with masking material 1402), according to some embodiments. Dielectric fill 1602 may be any suitable dielectric material. In some embodiments, dielectric fill 1602 is a regular-k or low-k dielectric material, such as silicon dioxide, or porous silicon dioxide, or flowable oxide. In some examples, a bottom surface of the deposited dielectric fill 1602 is polished to be substantially coplanar with a bottom surface of masking material 1402.

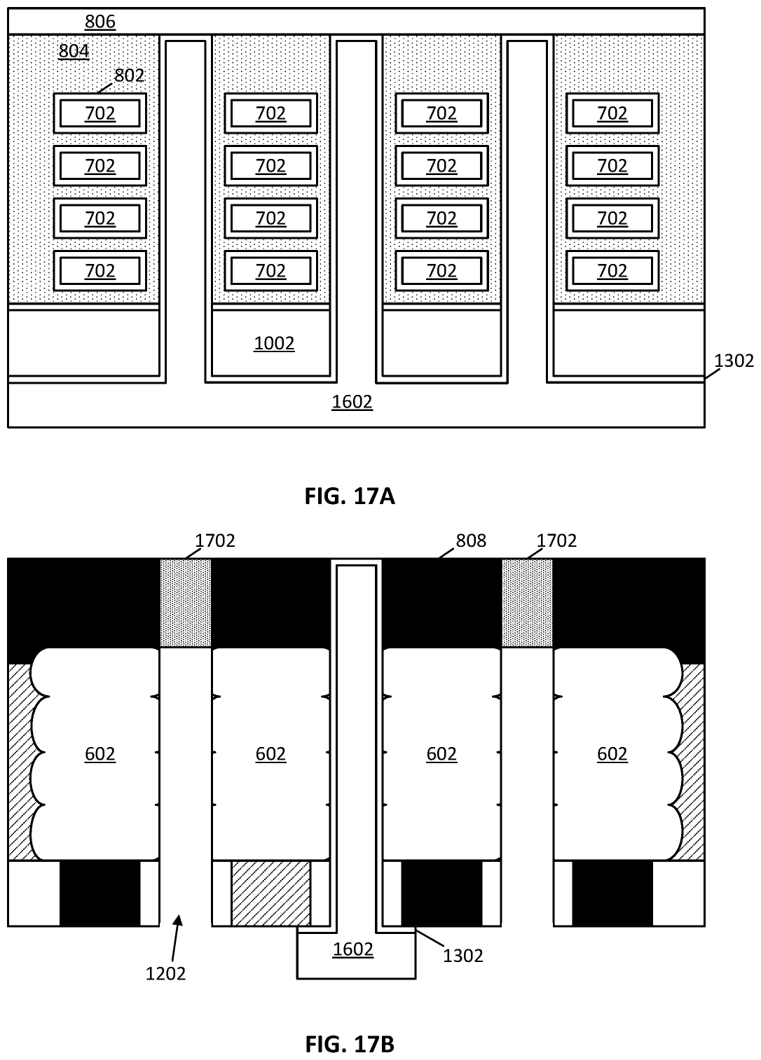

FIGS. 17A and 17B depict the cross-section views of the structure shown in FIGS. 16A and 16B, respectively, following the removal of masking material 1402 and the formation of topside contact links 1702 within backside trench recesses 1202, according to some embodiments. Following the removal of masking material 1402, exposed portions of dielectric liner 1302 (e.g., portions not covered by dielectric fill 1602) are removed using any suitable isotropic etching process. Topside contact links 1702 may be formed at the top end of the backside trench recesses 1202 and adjacent to topside conductive contacts 808. Accordingly, topside contact links 1702 provide electrical connection between adjacent topside conductive contacts 808. Topside contact links 1702 may include any suitable conductive material, such as tungsten, or the same conductive material as topside conductive contacts 808. According to some embodiments, topside contact links 1702 are formed from conductive material that is deposited within backside trench recesses 1202 and recessed to a final thickness such that the bottom surface of topside contact links 1702 is substantially coplanar with or above a bottom surface of topside conductive contacts 808 (when oriented as shown in FIG. 17B). In some other examples, topside contact links 1702 are selectively grown from the exposed sides of topside conductive contacts 808 at the top end of backside trench recesses 1202. Such selective growth may reduce the need for subsequent recess etching.

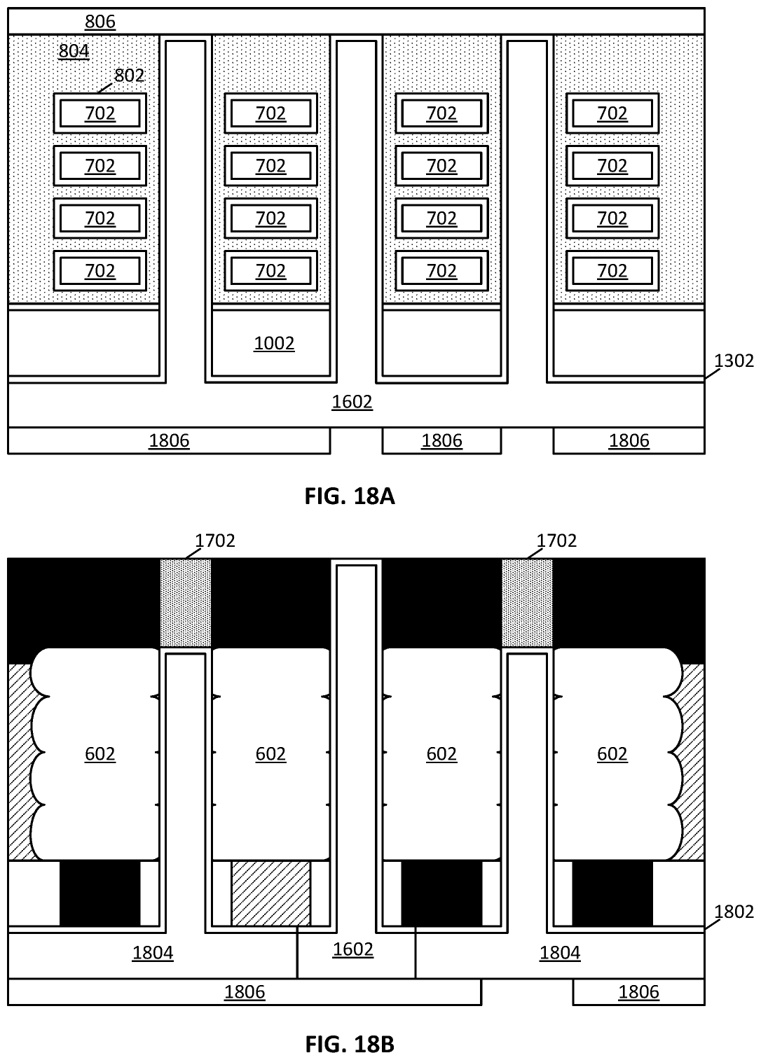

FIGS. 18A and 18B depict the cross-section views of the structure shown in FIGS. 17A and 17B, respectively, following the formation of another dielectric liner 1802 within the backside trench recesses 1202 below topside contact links 1702 and a dielectric fill 1804 on dielectric liner 1802, according to some embodiments. The formation and characteristics of dielectric liner 1802 may be substantially the same as discussed above for dielectric liner 1302, and the formation and characteristics of dielectric fill 1804 may be substantially the same as discussed above for dielectric fill 1602. The bottom surface of dielectric fill 1804 may be polished to be substantially coplanar with the bottom surface of dielectric fill 1602. According to some embodiments, a backside mask structure 1806 is formed on the bottom surface of dielectric fill 1602 and dielectric fill 1804 and patterned to provide an opening through backside mask structure 1806 over regions where backside conductive links are to be formed between adjacent gate structures or adjacent backside contacts. Backside mask structure 1806 may include any suitable hard mask material or photoresist.

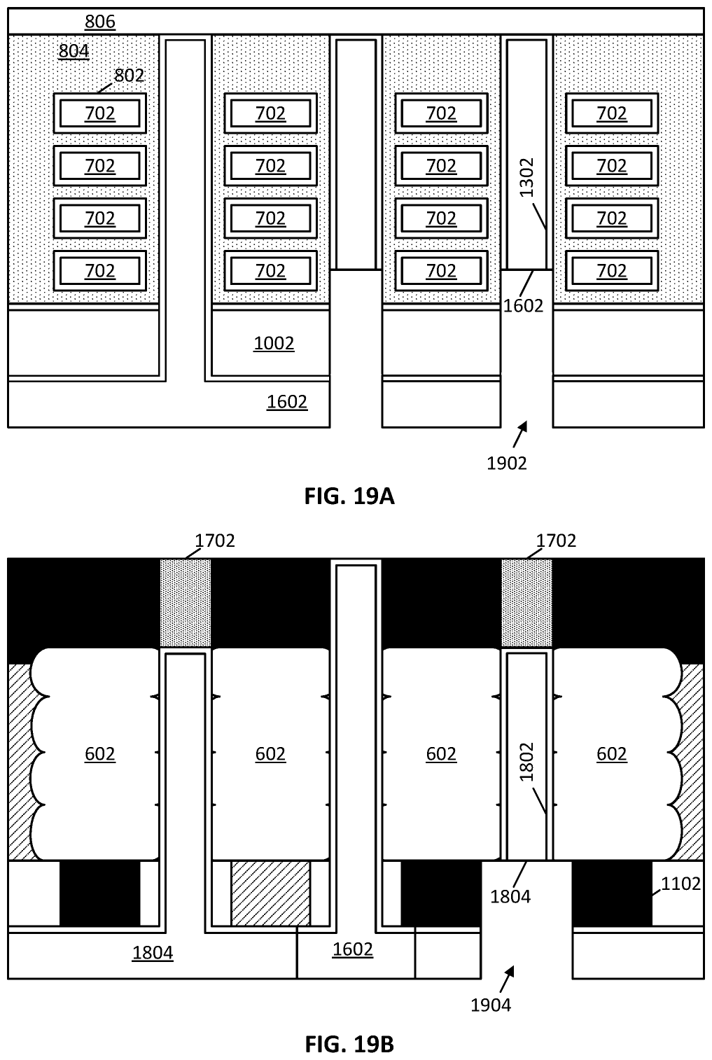

FIGS. 19A and 19B depict the cross-section views of the structure shown in FIGS. 18A and 18B, respectively, following the formation of first backside recesses 1902 through the gate trench, and second backside recesses 1904 through the source/drain trench, according to some embodiments. An RIE process may be used to etch away exposed material not protected by backside mask structure 1806. In some examples, an isotropic etch may be performed to remove any portions of dielectric liner 1302 within first backside recess 1902 and/or any portions of dielectric liner 1802 within second backside recess 1904. According to some embodiments, the removal of portions of dielectric fill 1602 within the gate trench occurs at least until bottom portions of the sidewalls of adjacent gate electrodes 804 are exposed within first backside recesses 1902, such as shown in the example of FIG. 19A. In a similar fashion, the removal of portions of dielectric fill 1804 within the source/drain trench (and any other adjacent dielectric materials) occurs until portions of the sidewalls of adjacent backside conductive contacts 1102 are exposed within second backside recesses 1904, such as shown in the example of FIG. 19B. In some embodiments, second backside recesses 1904 expose sidewalls along an entire thickness of the adjacent backside conductive contacts 1102, and may partially land on source/drain regions 602. Backside mask structure 1806 may be removed following the formation of first backside recesses 1902 and second backside recesses 1904.

FIGS. 20A and 20B depict the cross-section views of the structure shown in FIGS. 19A and 19B, respectively, following the formation of conductive gate links 2002 within first backside recesses 1902 and backside contact links 2004 within second backside recesses 1904, according to some embodiments. Conductive gate links 2002 may include any suitable conductive material, such as tungsten or any of the conductive materials noted above for gate electrode 804. In some examples, conductive gate links 2002 include the same conductive material as gate electrode 804 (e.g., tungsten, ruthenium, molybdenum, titanium, tantalum, or cobalt). Backside contact links 2004 may include any suitable conductive material, such as tungsten or any of the materials noted above for backside conductive contacts 1102. In some examples, backside contact links 2004 include the same conductive material as backside conductive contacts 1102 (e.g., tungsten, ruthenium, molybdenum, titanium, tantalum, or cobalt).

Conductive material may be deposited within first backside recesses 1902 and second backside recesses 1904 and subsequently recessed to form conductive gate links 2002 and backside contact links 2004, respectively. In some examples, conductive gate links 2002 have a bottom surface that is substantially coplanar with, or within 5 nm of, a bottom surface of gate electrode 804. Similarly, in some examples, backside contact links 2004 have a bottom surface that is substantially coplanar with, or within 5 nm of, a bottom surface of backside conductive contacts 1102. Other examples may be configured differently, such as the case where the bottom surfaces of gate electrodes 804 and backside conductive contacts 1102 are lower than bottom surfaces of conductive gate links 2002 and backside contact links 2004 (when the given integrated circuit structure is oriented as shown in FIGS. 20A-B).

According to some embodiments, dielectric fill 1602 and dielectric liner 1302 form dielectric walls within the gate trench to separate adjacent gate structures and may extend into the adjacent source/drain trench to separate adjacent source or drain regions 602. Similarly, dielectric fill 1804 and dielectric liner 1802 form dielectric walls within the source/drain trench to separate adjacent source or drain regions 602, according to some embodiments. Note that the use of topside contact link 1702 and backside contact link 2004 to connect between the topside and backside contacts of the same adjacent pair of source or drain regions 602 can reduce the contact resistance to the source or drain regions 602, according to some examples.

According to some embodiments, a remainder of first backside recesses 1902 below conductive gate links 2002 is filled with a dielectric fill 2006, and a remainder of second backside recesses 1904 below backside contact links 2004 is filled with a dielectric fill 2008. Each of dielectric fill 2006 and dielectric fill 2008 can be any suitable dielectric material, such as silicon dioxide. In some embodiments, a bottom surface of dielectric fill 2006 and dielectric 2008 may be polished to be substantially coplanar with a bottom surface of dielectric fill 1602 and/or dielectric fill 1804. In some embodiments, following the formation of dielectric fill 2006 and dielectric fill 2008, the bottom of the structure is polished back until the bottom surface of base dielectric structure 1002 is exposed.

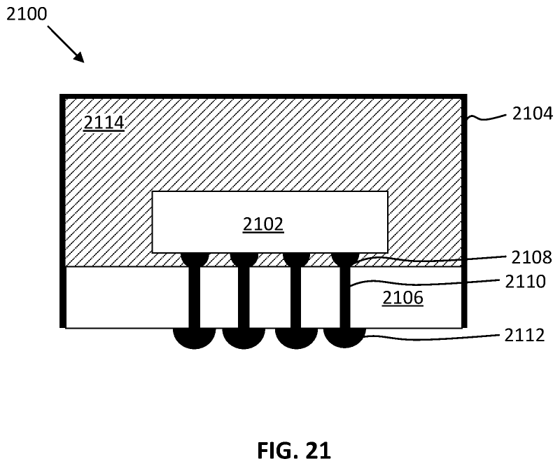

FIG. 21 illustrates an example embodiment of a chip package 2100. As can be seen, chip package 2100 includes one or more dies 2102. One or more dies 2102 may include at least one integrated circuit having semiconductor devices, such as any of the semiconductor devices disclosed herein. One or more dies 2102 may include any other circuitry used to interface with other devices formed on the dies, or other devices connected to chip package 2100, in some example configurations.

As can be further seen, chip package 2100 includes a housing 2104 that is bonded to a package substrate 2106. The housing 2104 may be any standard or proprietary housing, and provides, for example, electromagnetic shielding and environmental protection for the components of chip package 2100. The one or more dies 2102 may be conductively coupled to a package substrate 2106 using connections 2108, which may be implemented with any number of standard or proprietary connection mechanisms, such as solder bumps, ball grid array (BGA), pins, or wire bonds, to name a few examples. Package substrate 2106 may be any standard or proprietary package substrate, but in some cases includes a dielectric material having conductive pathways (e.g., including conductive vias and lines) extending through the dielectric material between the faces of package substrate 2106, or between different locations on each face. In some embodiments, package substrate 2106 may have a thickness less than 1 millimeter (e.g., between 0.1 millimeters and 0.5 millimeters), although any number of package geometries can be used. Additional conductive contacts 2112 may be disposed at an opposite face of package substrate 2106 for conductively contacting, for instance, a printed circuit board (PCB). One or more vias 2110 extend through a thickness of package substrate 2106 to provide conductive pathways between one or more of connections 2108 to one or more of contacts 2112. Vias 2110 are illustrated as single straight columns through package substrate 2106 for ease of illustration, although other configurations can be used (e.g., damascene, dual damascene, through-silicon via). In still other embodiments, vias 2110 are fabricated by multiple smaller stacked vias, or are staggered at different locations across package substrate 2106. In the illustrated embodiment, contacts 2112 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 2112, to inhibit shorting.

In some embodiments, a mold material 2114 may be disposed around the one or more dies 2102 included within housing 2104 (e.g., between dies 2102 and package substrate 2106 as an underfill material, as well as between dies 2102 and housing 2104 as an overfill material). Although the dimensions and qualities of the mold material 2114 can vary from one embodiment to the next, in some embodiments, a thickness of mold material 2114 is less than 1 millimeter. Example materials that may be used for mold material 2114 include epoxy mold materials, as suitable. In some cases, the mold material 2114 is thermally conductive, in addition to being electrically insulating.

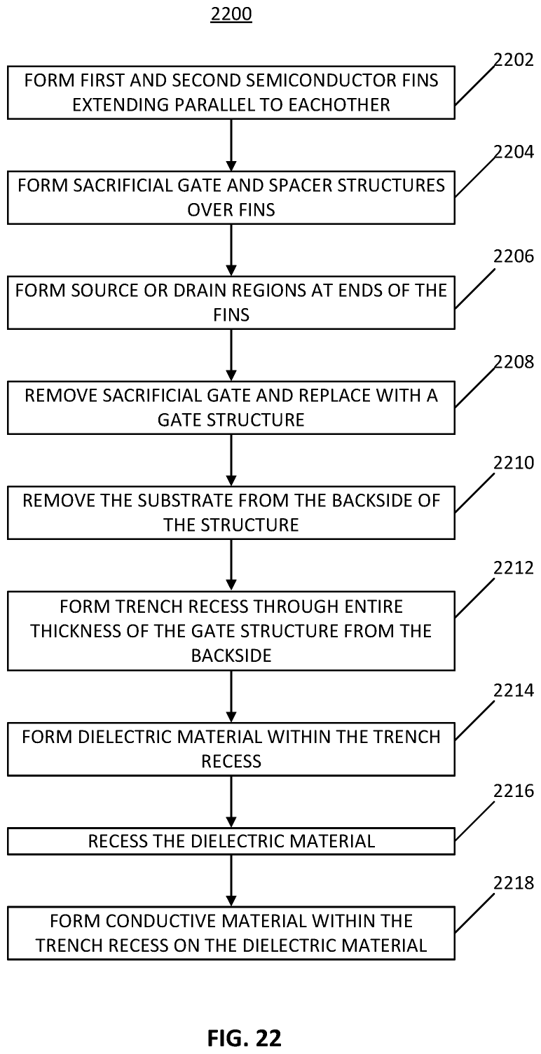

FIG. 22 is a flow chart of a method 2200 for forming at least a portion of an integrated circuit, according to an embodiment. Various operations of method 2200 may be illustrated in FIGS. 2A-20A and 2B-20B. However, the correlation of the various operations of method 2200 to the specific components illustrated in the aforementioned figures is not intended to imply any structural and/or use limitations. Rather, the aforementioned figures provide one example embodiment of method 2200. Other operations may be performed before, during, or after any of the operations of method 2200. Other operations may be performed before, during, or after any of the operations of method 2200. For example, method 2200 does not explicitly describe various processes that are performed to form common transistor structures. Some of the operations of method 2200 may be performed in a different order than the illustrated order.

Method 2200 begins with operation 2202 where a plurality of parallel semiconductor fins, including at least a first fin and a second fin, are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric fill is formed around subfin portions of the fins. In some embodiments, the dielectric fill extends between each pair of adjacent parallel fins and runs lengthwise in the same direction as the fins. In some embodiments, the anisotropic etching process that forms the fins also etches into a portion of the substrate and the dielectric fill may be formed within the recessed portions of the substrate. Accordingly, the dielectric fill acts as shallow trench isolation (STI) between adjacent fins. The dielectric fill may be any suitable dielectric material, such as silicon dioxide.

Method 2200 continues with operation 2204 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins)). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures, such as on sidewalls of the sacrificial gate. According to some embodiments, the spacer structures may be any suitable dielectric material, such as silicon nitride or silicon oxynitride.

Method 2200 continues with operation 2206 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon with n-type dopants) or PMOS source or drain regions (e.g., epitaxial SiGe with p-type dopants). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions. According to some embodiments, internal gate spacers may be formed during the source drain processing (e.g., after removing the exposed fins but prior to epi growth of source/drain regions, using a lateral etch process that selectively recesses sacrificial material of the channel region and then filling that recess with internal gate spacer material).

Method 2200 continues with operation 2208 where the sacrificial gate is removed and replaced with a gate structure. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples.

Method 2200 continues with operation 2210 where the substrate is removed from the backside to expose the underside of the dielectric fill around the base of the fins. According to some embodiments, the substrate is polished away via CMP or another grinding process to remove the substrate material. The substrate may be thinned at least until the bottom surface of the dielectric fill is exposed from the backside of the structure. In some examples, portions of the subfin regions and/or any sacrificial material replacing the subfin regions may also be exposed from the backside.

Method 2200 continues with operation 2212 where a backside trench recess is formed through at least an entire thickness of the gate structure between the semiconductor material of the first fin and second fin. The backside trench recess may be formed using an RIE-based metal gate etch process that iteratively etches through portions of the gate electrode while simultaneously protecting the sidewalls of the recess from lateral etching to provide a high height-to-width aspect ratio final recess (e.g., aspect ratio of 5:1 or higher, or 10:1 or higher). The trench recess may also extend along the first direction to separate both adjacent gate structures of adjacent devices and the adjacent source or drain regions of the adjacent devices.

Method 2200 continues with operation 2214 where one or more dielectric materials are formed within the backside trench recess to form a dielectric wall between adjacent gate structures. Because the dielectric wall is formed after the formation of the gate structure, the gate dielectric of the gate structure does not extend over the entire sidewall surface of the dielectric wall within the gate trench. In other words, the dielectric wall directly contacts the gate electrode on either side of the dielectric wall (e.g., with no gate dielectric between them). In some examples, the dielectric wall includes only silicon dioxide or silicon nitride. In some examples, the dielectric wall includes a dielectric liner and a dielectric fill on the dielectric liner within a remaining volume of the backside trench recess. The dielectric liner may include a high-k dielectric material (e.g., materials with a dielectric constant higher than that of silicon oxide or higher than 3.9) while the dielectric fill may include a low-k dielectric material (e.g., materials with a dielectric constant equal to or lower than that of silicon oxide or equal to or lower than 3.9). In one example, the dielectric liner is silicon nitride and the dielectric fill is silicon dioxide.

Method 2200 continues with operation 2216 where a bottom portion of the dielectric wall is removed from the backside to form a backside cavity beneath the dielectric wall. A dielectric RIE process may be used to remove the dielectric material of the dielectric wall from the backside while minimizing any removal of the exposed gate electrode material. The recess may extend across an entirety of the dielectric wall within the gate trench to expose sidewalls of the gate electrodes of both adjacent gate structures.

Method 2200 continues with operation 2218 where a conductive material is deposited within the backside cavity to form a conductive gate link. The conductive gate link is formed directly on a lower surface of the dielectric wall and forms a conductive bridge between the adjacent gate electrodes on either side of the dielectric wall. The conductive gate link may include any suitable conductive material, and may include any of the conductive materials noted above for the gate electrode, such as tungsten or molybdenum. Since the conductive gate link is formed from the backside of the structure, the conductive gate link extends between the adjacent gate electrodes along the bottom of the gate trench.

### Example System

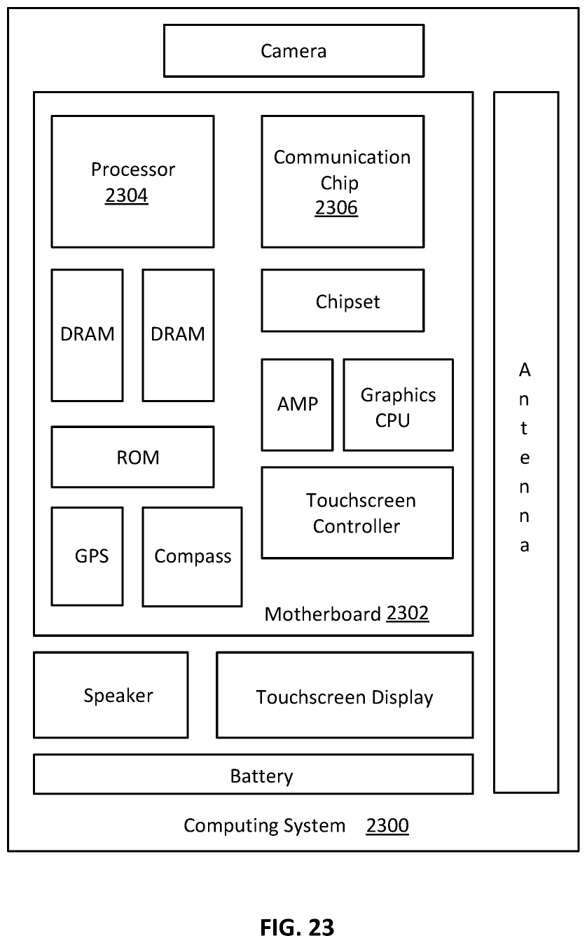

FIG. 23 is an example computing system implemented with one or more of the integrated circuit structures as disclosed herein, in accordance with some embodiments of the present disclosure. As can be seen, the computing system 2300 houses a motherboard 2302. The motherboard 2302 may include a number of components, including, but not limited to, a processor 2304 and at least one communication chip 2306, each of which can be physically and electrically coupled to the motherboard 2302, or otherwise integrated therein. As will be appreciated, the motherboard 2302 may be, for example, any printed circuit board (PCB), whether a main board, a daughterboard mounted on a main board, or the only board of system 2300, etc.

Depending on its applications, computing system 2300 may include one or more other components that may or may not be physically and electrically coupled to the motherboard 2302. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 2300 may include one or more integrated circuit structures or devices configured in accordance with an example embodiment (e.g., a module including an integrated circuit having semiconductor devices with a series of dielectric walls formed from the backside of the structure, as variously provided herein). In some embodiments, multiple functions can be integrated into one or more chips (e.g., for instance, note that the communication chip 2306 can be part of or otherwise integrated into the processor 2304).

The communication chip 2306 enables wireless communications for the transfer of data to and from the computing system 2300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2306 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2300 may include a plurality of communication chips 2306. For instance, a first communication chip 2306 may be dedicated to shorter range wireless communications such as Wi-Fi and Bluetooth and a second communication chip 2306 may be dedicated to longer range wireless communications such as GPS, EDGE, GPRS, CDMA, WiMAX, LTE, Ev-DO, and others.

The processor 2304 of the computing system 2300 includes an integrated circuit die packaged within the processor 2304. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 2306 also may include an integrated circuit die packaged within the communication chip 2306. In accordance with some such example embodiments, the integrated circuit die of the communication chip includes one or more semiconductor devices as variously described herein. As will be appreciated in light of this disclosure, note that multi-standard wireless capability may be integrated directly into the processor 2304 (e.g., where functionality of any chips 2306 is integrated into processor 2304, rather than having separate communication chips). Further note that processor 2304 may be a chip set having such wireless capability. In short, any number of processor 2304 and/or communication chips 2306 can be used. Likewise, any one chip or chip set can have multiple functions integrated therein.

In various implementations, the computing system 2300 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

### Further Example Embodiments

The following examples pertain to further embodiments, from which numerous permutations and configurations will be apparent.

Example 1 is an integrated circuit that includes a first semiconductor device having a first semiconductor region extending in a first direction from a first source or drain region and a first gate electrode around the first semiconductor region, and a second semiconductor device having a second semiconductor region extending in the first direction from a second source or drain region and a second gate electrode around the second semiconductor region. The second semiconductor device is spaced from the first semiconductor device in a second direction different from the first direction. The integrated circuit further includes a dielectric structure beneath the first gate electrode and the second gate electrode, a dielectric wall extending along the first direction between the first gate electrode and the second gate electrode and extending in a third direction along at least an entire height of the first gate electrode and the second gate electrode, and a conductive bridge extending through a bottom portion of the dielectric wall along the second direction and contacting the first gate electrode and the second gate electrode. The conductive bridge is on a top surface of the dielectric structure.

Example 2 includes the integrated circuit of Example 1, wherein the dielectric wall comprises a dielectric layer along one or more edges of the dielectric wall and a dielectric fill in a remaining volume of the dielectric wall.

Example 3 includes the integrated circuit of Example 2, wherein the dielectric layer comprises a high-k dielectric material.

Example 4 includes the integrated circuit of any one of Examples 1-3, wherein the first semiconductor region comprises a plurality of first semiconductor nanoribbons, and the second semiconductor region comprises a plurality of second semiconductor nanoribbons.

Example 5 includes the integrated circuit of Example 4, wherein the plurality of first semiconductor nanoribbons and the plurality of second semiconductor nanoribbons comprise germanium, silicon, or a combination thereof.

Example 6 includes the integrated circuit of Example 4 or 5, wherein a plane extending along the first direction and along the second direction intersects the conductive bridge, at least one of the plurality of first semiconductor nanoribbons, and at least one of the plurality of second semiconductor nanoribbons.

Example 7 includes the integrated circuit of any one of Examples 1-6, further comprising a first gate dielectric layer around the first semiconductor region, and a second gate dielectric layer around the second semiconductor region, such that the first gate dielectric layer is between the first semiconductor region and the first gate electrode, and the second gate dielectric layer is between the second semiconductor region and the second gate electrode.

Example 8 includes the integrated circuit of Example 7, wherein the first and second gate dielectric layers are not present on any sidewall of the dielectric wall.

Example 9 includes the integrated circuit of any one of Examples 1-8, wherein the dielectric wall extends along the first direction between the first source or drain region and the second source or drain region.

Example 10 includes the integrated circuit of Example 9, wherein the conductive bridge is a first conductive bridge, and the integrated circuit further includes a first contact on a top surface of the first source or drain region, a second contact on a top surface of the second source or drain region, and a second conductive bridge extending through a top portion of the dielectric wall along the second direction and contacting the first contact and the second contact.

Example 11 includes the integrated circuit of Example 10, further comprising a third contact on a bottom surface of the first source or drain region, a fourth contact on a bottom surface of the second source or drain region, and a third conductive bridge extending through a bottom portion of the dielectric wall along the second direction and contacting the third contact and the fourth contact.

Example 12 includes the integrated circuit of Example 9, wherein the conductive bridge is a first conductive bridge, and the integrated circuit further comprises a first contact on a bottom surface of the first source or drain region, a second contact on a bottom surface of the second source or drain region, and a second conductive bridge extending through a bottom portion of the dielectric wall along the second direction and contacting the first contact and the second contact.

Example 13 includes the integrated circuit of any one of Examples 1-12, wherein the dielectric wall is a first dielectric wall, and the integrated circuit further comprises a second dielectric wall extending along the first direction between the first semiconductor device and a third semiconductor device, the second dielectric wall extending through an entire thickness of the first gate electrode, and a third dielectric wall extending along the first direction between the second semiconductor device and a fourth semiconductor device, the third dielectric wall extending through an entire thickness of the second gate electrode.

Example 14 includes the integrated circuit of Example 13, wherein the conductive bridge is a first conductive bridge, and the integrated circuit further comprises a second conductive bridge extending through a bottom portion of the corresponding dielectric wall along the second direction and contacting a first source or drain contact and a second source or drain contact, and/or a third conductive bridge extending through a top portion of the corresponding dielectric wall along the second direction and contacting a third source or drain contact and a fourth source or drain contact.

Example 15 is a printed circuit board comprising the integrated circuit of any one of Examples 1-14.

Example 16 is an electronic device that includes a chip package having one or more dies. At least one of the one or more dies includes a first semiconductor region extending in a first direction from a first source or drain region, a second semiconductor region extending in the first direction from a second source or drain region, a gate electrode around each of the first semiconductor region and the second semiconductor region, a dielectric structure beneath the gate electrode, and a dielectric wall between the first semiconductor region and the second semiconductor region. The second semiconductor region is spaced from the first semiconductor region in a second direction different from the first direction. A portion of the gate electrode extends through a bottom portion of the dielectric wall along the second direction, such that the portion of the gate electrode is on a top surface of the dielectric structure.

Example 17 includes the electronic device of Example 16, wherein the dielectric wall comprises a dielectric layer along one or more edges of the dielectric wall and a dielectric fill in a remaining volume of the dielectric wall.

Example 18 includes the electronic device of Example 17, wherein the dielectric layer comprises a high-k dielectric material.

Example 19 includes the electronic device of any one of Examples 16-18, wherein the first semiconductor region comprises a plurality of first semiconductor nanoribbons, and the second semiconductor region comprises a plurality of second semiconductor nanoribbons.

Example 20 includes the electronic device of Example 19, wherein the plurality of first semiconductor nanoribbons and the plurality of second semiconductor nanoribbons comprise germanium, silicon, or a combination thereof.

Example 21 includes the electronic device of Example 19 or 20, wherein a plane extending along the first direction and along the second direction intersects the portion of the gate electrode on the top surface of the dielectric structure, at least one of the plurality of first semiconductor nanoribbons, and at least one of the plurality of second semiconductor nanoribbons.

Example 22 includes the electronic device of any one of Examples 16-21, wherein the at least one of the one or more dies further comprises a gate dielectric layer around the first semiconductor region and the second semiconductor region, such that the gate dielectric layer is between the first semiconductor region and the gate electrode and is between the second semiconductor region and the gate electrode.

Example 23 includes the electronic device of Example 22, wherein the gate dielectric layer is not present on any sidewall of the dielectric wall.

Example 24 includes the electronic device of any one of Examples 16-23, wherein the dielectric wall extends along the first direction between the first source or drain region and the second source or drain region.

Example 25 includes the electronic device of Example 24, wherein the at least one of the one or more dies further comprises a third contact on a bottom surface of the first source or drain region, a fourth contact on a bottom surface of the second source or drain region, and a conductive bridge extending through a bottom portion of the dielectric wall along the second direction and contacting the third contact and the fourth contact.

Example 26 includes the electronic device of Example 25, wherein the conductive bridge is a first conductive bridge and the at least one of the one or more dies further comprises a first contact on a top surface of the first source or drain region; a second contact on a top surface of the second source or drain region; and a second conductive bridge extending through a top portion of the dielectric wall along the second direction and contacting the first contact and the second contact.

Example 27 includes the electronic device of any one of Examples 16-26, wherein the dielectric wall is a first dielectric wall and the at least one of the one or more dies further comprises a second dielectric wall extending along the first direction between the first semiconductor region and a third semiconductor region, the second dielectric wall extending through an entire thickness of the gate electrode, and a third dielectric wall extending along the first direction between the second semiconductor region and a fourth semiconductor region, the third dielectric wall extending through an entire thickness of the gate electrode.

Example 28 includes the electronic device of any one of Examples 16-27, further comprising a printed circuit board, wherein the chip package is coupled to the printed circuit board.

Example 29 is a method of forming an integrated circuit. The method includes forming a first fin comprising first semiconductor material and a second fin comprising second semiconductor material, the first and second fins extending above a substrate and each extending parallel to each other in a first direction, forming a first source or drain region at an end of the first fin and a second source or drain region at an end of the second fin, forming a gate electrode extending over the first fin and the second fin in a second direction different from the first direction, removing the substrate from a backside of the integrated circuit, after removing the substrate, forming a recess through an entire thickness of the gate electrode from the backside between the first semiconductor material and the second semiconductor material, the recess further extending in the first direction between the first source or drain region and the second source or drain region, forming a dielectric material within the recess; recessing a portion of the dielectric material between the first semiconductor material and the second semiconductor material, forming a conductive material on the dielectric material, the conductive material being within the recess and contacting the gate electrode, and forming a dielectric layer on the conductive material.

Example 30 includes the method of Example 29, further comprising forming a gate dielectric layer around the first semiconductor material and the second semiconductor material before forming the gate electrode.

Example 31 includes the method of Example 29 or 30, wherein forming the recess comprises forming the recess through an entire thickness of the gate electrode.

Example 32 includes the method of any one of Examples 29-31, wherein the conductive material is first conductive material and the method further comprises recessing another portion of the dielectric material between the first source or drain region and the second source or drain region, and forming second conductive material on the dielectric material within the recess between the first source or drain region and the second source or drain region.

Example 33 is an integrated circuit that includes a first semiconductor device having a first semiconductor region extending in a first direction from a first source or drain region and a first gate electrode around the first semiconductor region, and a second semiconductor device having a second semiconductor region extending in the first direction from a second source or drain region and a second gate electrode around the second semiconductor region. The second semiconductor device is spaced from the first semiconductor device in a second direction different from the first direction. The integrated circuit further includes a first contact on a top surface of the first source or drain region and a second contact on a top surface of the second source or drain region, a third contact on a bottom surface of the first source or drain region and a fourth contact on a bottom surface of the second source or drain region, a dielectric wall extending along the first direction between the first gate electrode and the second gate electrode and between the first source or drain region and the second source or drain region, a first conductive bridge extending through a bottom portion of the dielectric wall along the second direction and contacting the third contact and the fourth contact, and a second conductive bridge extending through a top portion of the dielectric wall along the second direction and contacting the first contact and the second contact.

Example 34 includes the integrated circuit of Example 33, wherein the dielectric wall comprises a dielectric layer along one or more edges of the dielectric wall and a dielectric fill in a remaining volume of the dielectric wall.

Example 35 includes the integrated circuit of Example 34, wherein the dielectric layer comprises a high-k dielectric material.

Example 36 includes the integrated circuit of any one of Examples 33-35, wherein the first semiconductor region comprises a plurality of first semiconductor nanoribbons, and the second semiconductor region comprises a plurality of second semiconductor nanoribbons.

Example 37 includes the integrated circuit of Example 36, wherein the plurality of first semiconductor nanoribbons and the plurality of second semiconductor nanoribbons comprise germanium, silicon, or a combination thereof.

Example 38 includes the integrated circuit of any one of Examples 33-37, further comprising a gate dielectric layer around the first semiconductor region and the second semiconductor region, such that the gate dielectric layer is between the first semiconductor region and the first gate electrode and is between the second semiconductor region and the second gate electrode.

Example 39 includes the integrated circuit of Example 38, wherein the gate dielectric layer is not present on any sidewall of the dielectric wall.

Example 40 includes the integrated circuit of any one of Examples 33-39, further comprising a third conductive bridge extending through a bottom portion of the dielectric wall along the second direction and contacting the first gate electrode and the second gate electrode.

Example 41 includes the integrated circuit of any one of Examples 33-40, wherein the dielectric wall is a first dielectric wall and the integrated circuit further comprises a second dielectric wall extending along the first direction between the first semiconductor device and a third semiconductor device, the second dielectric wall extending through an entire thickness of the first gate electrode, and a third dielectric wall extending along the first direction between the second semiconductor device and a fourth semiconductor device, the third dielectric wall extending through an entire thickness of the second gate electrode.

Example 42 is a printed circuit board comprising the integrated circuit of any one of Examples 33-41.

It will be appreciated that in some embodiments, the various components of the computing system 2300 may be combined or integrated in a system-on-a-chip (SoC) architecture. In some embodiments, the components may be hardware components, firmware components, software components or any suitable combination of hardware, firmware or software.

What is claimed is:

1. An integrated circuit comprising:
a first semiconductor device having a first semiconductor region extending in a first direction from a first source or drain region, and a first gate electrode around the first semiconductor region;
a second semiconductor device having a second semiconductor region extending in the first direction from a second source or drain region, and a second gate electrode around the second semiconductor region, the second semiconductor device spaced from the first semiconductor device in a second direction different from the first direction;
a dielectric structure beneath the first gate electrode and the second gate electrode;
a dielectric wall extending along the first direction between the first gate electrode and the second gate electrode and extending in a third direction along at least an entire height of the first gate electrode and the second gate electrode; and
a conductive bridge extending through a bottom portion of the dielectric wall along the second direction and contacting the first gate electrode and the second gate electrode, wherein the conductive bridge is on a top surface of the dielectric structure.

2. The integrated circuit of claim 1, wherein the first semiconductor region comprises a plurality of first semiconductor nanoribbons, and the second semiconductor region comprises a plurality of second semiconductor nanoribbons.

3. The integrated circuit of claim 2, wherein a plane extending along the first direction and along the second direction intersects the conductive bridge, at least one of the plurality of first semiconductor nanoribbons, and at least one of the plurality of second semiconductor nanoribbons.

4. The integrated circuit of claim 1, further comprising a first gate dielectric layer around the first semiconductor region, and a second gate dielectric layer around the second semiconductor region, such that the first gate dielectric layer is between the first semiconductor region and the first gate electrode, and the second gate dielectric layer is between the second semiconductor region and the second gate electrode.

5. The integrated circuit of claim 4, wherein the first and second gate dielectric layers are not present on any sidewall of the dielectric wall.

6. The integrated circuit of claim 1, wherein the dielectric wall extends along the first direction between the first source or drain region and the second source or drain region.

7. The integrated circuit of claim 6, wherein the conductive bridge is a first conductive bridge, and the integrated circuit further comprises:
a first contact on a top surface of the first source or drain region;
a second contact on a top surface of the second source or drain region; and
a second conductive bridge extending through a top portion of the dielectric wall along the second direction and contacting the first contact and the second contact.

8. The integrated circuit of claim 7, further comprising:
a third contact on a bottom surface of the first source or drain region;
a fourth contact on a bottom surface of the second source or drain region; and
a third conductive bridge extending through a bottom portion of the dielectric wall along the second direction and contacting the third contact and the fourth contact.

9. A printed circuit board comprising the integrated circuit of claim 1.

10. An electronic device, comprising:
a chip package comprising one or more dies, at least one of the one or more dies comprising
a first semiconductor region extending in a first direction from a first source or drain region;
a second semiconductor region extending in the first direction from a second source or drain region, the second semiconductor region spaced from the first semiconductor region in a second direction different from the first direction;
a gate electrode around each of the first semiconductor region and the second semiconductor region;
a dielectric structure beneath the gate electrode; and
a dielectric wall between the first semiconductor region and the second semiconductor region, wherein a portion of the gate electrode extends through a bottom portion of the dielectric wall along the second direction, such that the portion of the gate electrode is on a top surface of the dielectric structure.

11. The electronic device of claim 10, wherein the dielectric wall comprises a dielectric layer along one or more edges of the dielectric wall and a dielectric fill in a remaining volume of the dielectric wall.

12. The electronic device of claim 10, wherein the first semiconductor region comprises a plurality of first semiconductor nanoribbons, and the second semiconductor region comprises a plurality of second semiconductor nanoribbons.

13. The electronic device of claim 12, wherein a plane extending along the first direction and along the second direction intersects the portion of the gate electrode on the top surface of the dielectric structure, at least one of the plurality of first semiconductor nanoribbons, and at least one of the plurality of second semiconductor nanoribbons.

14. The electronic device of claim 10, wherein the dielectric wall extends along the first direction between the first source or drain region and the second source or drain region.

15. The electronic device of claim 10, wherein the dielectric wall is a first dielectric wall and the at least one of the one or more dies further comprises:
a second dielectric wall extending along the first direction between the first semiconductor region and a third semiconductor region, the second dielectric wall extending through an entire thickness of the gate electrode; and
a third dielectric wall extending along the first direction between the second semiconductor region and a fourth semiconductor region, the third dielectric wall extending through an entire thickness of the gate electrode.

16. An integrated circuit comprising:
a first semiconductor device having a first semiconductor region extending in a first direction from a first source or drain region and a first gate electrode around the first semiconductor region;
a second semiconductor device having a second semiconductor region extending in the first direction from a second source or drain region and a second gate electrode around the second semiconductor region, the second semiconductor device spaced from the first semiconductor device in a second direction different from the first direction;
a first contact on a top surface of the first source or drain region, and a second contact on a top surface of the second source or drain region;
a third contact on a bottom surface of the first source or drain region, and a fourth contact on a bottom surface of the second source or drain region;
a dielectric wall extending along the first direction between the first gate electrode and the second gate electrode and between the first source or drain region and the second source or drain region;
a first conductive bridge extending through a bottom portion of the dielectric wall along the second direction and contacting the third contact and the fourth contact; and
a second conductive bridge extending through a top portion of the dielectric wall along the second direction and contacting the first contact and the second contact.

17. The integrated circuit of claim 16, wherein the first semiconductor region comprises a plurality of first semiconductor nanoribbons, and the second semiconductor region comprises a plurality of second semiconductor nanoribbons.

18. The integrated circuit of claim 16, further comprising a gate dielectric layer around the first semiconductor region and the second semiconductor region, such that the gate dielectric layer is between the first semiconductor region and the first gate electrode and is between the second semiconductor region and the second gate electrode.

19. The integrated circuit of claim 16, further comprising a third conductive bridge extending through a bottom portion of the dielectric wall along the second direction and contacting the first gate electrode and the second gate electrode.

20. The integrated circuit of claim 16, wherein the dielectric wall is a first dielectric wall and the integrated circuit further comprises:
a second dielectric wall extending along the first direction between the first semiconductor device and a third semiconductor device, the second dielectric wall extending through an entire thickness of the first gate electrode; and
a third dielectric wall extending along the first direction between the second semiconductor device and a fourth semiconductor device, the third dielectric wall extending through an entire thickness of the second gate electrode.
